(19) United States
(12) Patent Application Publication
(10) Pub. No.: US 2026/0358634 A1
(43) Pub. Date: Nov. 12, 2026

(54) DISPLAY DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Yosuke TSUKAMOTO, Atsugi, Kanagawa (JP); Akio ENDO, Atsugi, Kanagawa (JP); Hisao IKEDA, Zama, Kanagawa (JP); Kazuhiko FUJITA, Hiratsuka, Kanagawa (JP); Junya MARUYAMA, Ebina, Kanagawa (JP); Ryo HATSUMI, Hadano, Kanagawa (JP); Daiki NAKAMURA, Atsugi, Kanagawa (JP); Takeya HIROSE, Atsugi, Kanagawa (JP)

(21) Appl. No.: 19/134,773

(22) PCT Filed: Dec. 15, 2023
(86) PCT No.: PCT/IB2023/062745

§ 371 Date: Jun. 2, 2025

(30) Foreign Application Priority Data
Dec. 22, 2022 (JP) 2022-205597

(51) Int. Cl. G02B 27/01

(52) U.S. Cl. CPC G02B 27/0172; G02B 2027/0178

(57) ABSTRACT

A display device and an electronic device that enable a wide field of view are provided. The display device includes a first display unit and a second display unit. The first display unit and the second display unit each include a display portion, a first mirror, a second mirror, a first lens, and a second lens. An image emitted from the display portion enters the second lens through the first mirror and the second mirror. The first mirror is positioned on a normal line passing through a center of gravity of the display portion. The second mirror is positioned on a straight line connecting centers of two lens surfaces of the second lens. The first mirror and the second mirror are placed so that their reflective surfaces are parallel to each other. The normal line passing through the center of gravity of the display portion and the straight line connecting the centers of the two lens surfaces of the second lens are not aligned with each other. The first lens is positioned on an optical path through which the image emitted from the display portion enters the second lens.

### TECHNICAL FIELD

One embodiment of the present invention relates to a display device or an electronic device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting apparatus, a lighting device, a power storage device, a memory device, an imaging device, an operation method thereof, and a manufacturing method thereof.

Note that in this specification and the like, a semiconductor device generally means a device that can function by utilizing semiconductor characteristics. A transistor and a semiconductor circuit are embodiments of semiconductor devices. In addition, in some cases, a memory device, a display device, an imaging device, or an electronic device includes a semiconductor device.

### BACKGROUND ART

Goggles-type devices and glasses-type devices have been developed as electronic devices for virtual reality (VR), augmented reality (AR), mixed reality (MR), and the like.

In addition, examples of a display device that can be used for a display panel include, typically, a display device including a liquid crystal element and a display device including an organic EL (Electro Luminescence) element, a light-emitting diode (LED), or the like.

A display device including an organic EL element does not need a backlight that is necessary for a liquid crystal display device; thus, a thin, lightweight, high-contrast, and low-power display device can be achieved. Patent Document 1, for example, discloses an example of a display device using an organic EL element.

### REFERENCE

### Patent Document

[Patent Document 1] Japanese Published Patent Application No. 2018-107444

### SUMMARY OF THE INVENTION

### Problems to be Solved by the Invention

A head-mounted display (HMD) used for AR, VR, or MR is used by a user wearing a device on his/her head. Thus, the user may feel discomfort, oppression, or constriction. Therefore, the HMD is desired to be reduced in size and weight. Moreover, in the case where the HMD is used by a plurality of people, hygiene control (e.g., control of attachment of dust, bacteria, or viruses) of a fixing member or the like for mounting the device on a user's head might be insufficient.

Meanwhile, in the case of using the device as an aid in medical treatment, work, or the like, a screen does not need to be seen all the time. Thus, the device is desirably in a mode that can be accessed when an image is desired to be seen.

In view of the above, an object of one embodiment of the present invention is to provide a display device enabling a wide field of view. Another object is to provide a display device capable of displaying a three-dimensional image by a parallax method. Another object is to provide a display device capable of displaying a high-quality image. Another object is to provide a novel display device. Another object is to provide an electronic device including any of these display devices. Another object is to provide an electronic device that can be easily attached and detached.

Note that the description of these objects does not preclude the existence of other objects. In one embodiment of the present invention, there is no need to achieve all these objects. Other objects will be apparent from the description of the specification, the drawings, the claims, and the like, and other objects can be derived from the description of the specification, the drawings, the claims, and the like.

### Means for Solving the Problems

One embodiment of the present invention is a display device including a first display unit and a second display unit. The first display unit and the second display unit each include a display portion, a first mirror, a second mirror, a first lens, and a second lens. An image emitted from the display portion enters the second lens through the first mirror and the second mirror. The first mirror is positioned on a normal line passing through a center of gravity of the display portion. The second mirror is positioned on a straight line connecting centers of two lens surfaces of the second lens. The first mirror and the second mirror are placed so that their reflective surfaces are parallel to each other. The normal line passing through the center of gravity of the display portion and the straight line connecting the centers of the two lens surfaces of the second lens are not aligned with each other. The first lens is positioned on an optical path through which the image emitted from the display portion enters the second lens.

In the above display device, it is preferable that the first lens be positioned between the first mirror and the second mirror.

In the above display device, it is preferable that the first lens be positioned between the second mirror and the second lens.

In the above display device, it is preferable that the first lens function as a relay lens, and the second lens function as an eyepiece lens.

In the above display device, it is preferable that the first display unit include a first display panel, the first display panel include the display portion of the first display unit, the second display unit include a second display panel, and the second display panel include the display portion of the second display unit.

In the above display device, it is preferable that the first display unit and the second display unit include a third display panel, and the third display panel include the display portion of the first display unit and the display portion of the second display unit.

One embodiment of the present invention is a display device including a first display unit and a second display unit. The first display unit and the second display unit each include a display portion, a first mirror, a second mirror, a third mirror, a fourth mirror, a first lens, a second lens, and a third lens. The third mirror is positioned on a normal line passing through a center of gravity of the display portion. The first mirror is provided between the third mirror and the display portion. The second mirror is positioned on a straight line connecting centers of two lens surfaces of the third lens. The fourth mirror is provided between the second mirror and the third lens. The first lens is positioned between the first mirror and the second mirror. The second lens is positioned between the third mirror and the fourth mirror. In a case where the fourth mirror is not positioned on the straight line connecting the centers of the two lens surfaces of the third lens, an image emitted from the display portion enters the third lens through the first mirror, the first lens, and the second mirror. In a case where the fourth mirror is positioned on the straight line connecting the centers of the two lens surfaces of the third lens, an image emitted from the display portion enters the third lens through the third mirror, the second lens, and the fourth mirror.

In the above display device, it is preferable that the fourth mirror have a mechanism capable of one or both of translational movement and rotational movement.

In the above display device, it is preferable that the first lens and the second lens function as relay lenses, and the third lens function as an eyepiece lens.

In the above display device, it is preferable that the first display unit include a first display panel, the first display panel include the display portion of the first display unit, the second display unit include a second display panel, and the second display panel include the display portion of the second display unit.

In the above display device, it is preferable that the first display unit and the second display unit include a third display panel, and the third display panel include the display portion of the first display unit and the display portion of the second display unit.

One embodiment of the present invention is an electronic device including a housing in which the above display device is incorporated and an arm fastened to an upper portion of the housing. The arm is connected so as to be revolvable centering around a first point.

### Effect of the Invention

According to one embodiment of the present invention, a display device enabling a wide field of view can be provided. Alternatively, a display device capable of displaying a three-dimensional image by a parallax method can be provided. Alternatively, a display device capable of displaying a high-quality image can be provided. Alternatively, a novel display device can be provided. Alternatively, an electronic device including any of these display devices can be provided. Alternatively, an electronic device that can be easily attached and detached can be provided.

Note that the description of these effects does not preclude the existence of other effects. One embodiment of the present invention does not necessarily have all these effects. Other effects can be derived from the description of the specification, the drawings, and the claims.

### BRIEF DESCRIPTION OF THE DRAWINGS

FIG. 1 is a diagram illustrating a display device.

FIG. 2A and FIG. 2B are diagrams illustrating a display device.

FIG. 3A and FIG. 3B are diagrams illustrating a display device.

FIG. 4 is a diagram illustrating a display device.

FIG. 5A and FIG. 5B are diagrams illustrating a display device.

FIG. 6A and FIG. 6B are diagrams illustrating a display device.

FIG. 7A and FIG. 7B are diagrams illustrating a display device.

FIG. 8A and FIG. 8B are diagrams illustrating a display device.

FIG. 9A and FIG. 9B are diagrams illustrating a display device.

FIG. 10 is a diagram illustrating a display device.

FIG. 11A and FIG. 11B are diagrams illustrating a display device.

FIG. 12A and FIG. 12B are diagrams illustrating a display device.

FIG. 13A and FIG. 13B are diagrams illustrating a display device.

FIG. 14A is a diagram illustrating a display device. FIG. 14B is a diagram illustrating an image to be seen.

FIG. 15A to FIG. 15C are diagrams illustrating a display device.

FIG. 16 is a diagram illustrating a display device.

FIG. 17A and FIG. 17B are diagrams illustrating an electronic device.

FIG. 18A to FIG. 18C are diagrams illustrating a structure example of a display panel.

FIG. 19A and FIG. 19B are diagrams illustrating structure examples of display panels.

FIG. 20A to FIG. 20F are diagrams illustrating structure examples of pixels.

FIG. 21A and FIG. 21B are diagrams illustrating a structure example of a display panel.

FIG. 22 is a diagram illustrating a structure example of a display panel.

FIG. 23 is a diagram illustrating a structure example of a display panel.

FIG. 24 is a diagram illustrating a structure example of a display panel.

FIG. 25 is a diagram illustrating a structure example of a display panel.

FIG. 26 is a diagram illustrating a structure example of a display panel.

FIG. 27 is a diagram illustrating a structure example of a display panel.

FIG. 28 is a diagram illustrating a structure example of a display panel.

FIG. 29A and FIG. 29B are diagrams illustrating a vertical transistor.

FIG. 30A and FIG. 30B are diagrams illustrating a vertical transistor.

FIG. 31 is a diagram illustrating a usage example of an electronic device.

FIG. 32 is a diagram illustrating a usage example of an electronic device.

FIG. 33 is a diagram illustrating a usage example of an electronic device.

FIG. 34A to FIG. 34F are diagrams illustrating the size of a display region of a display device and a light-exposure region.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

In addition, even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitors are separately arranged in a plurality of positions.

In addition, one conductive layer has a plurality of functions of a wiring, an electrode, a terminal, and the like in some cases. In this specification, a plurality of names are used for the same component in some cases. Even in the case where components are illustrated in a circuit diagram as if they were directly connected to each other, the components may actually be connected to each other through one or more conductive layers; in this specification, even such a structure is included in the category of direct connection.

### Embodiment 1

In this embodiment, a display device and an electronic device of embodiments of the present invention will be described.

One embodiment of the present invention is a display device. The display device of one embodiment of the present invention includes a pair of left and right display units. The pair of left and right display units is composed of a first display unit and a second display unit. With such a structure, a display device capable of displaying a three-dimensional image by a parallax method can be provided.

Furthermore, the first display unit and the second display unit each include a display portion and an optical unit. In the first display unit, an image emitted from the display portion is seen by one of left and right eyes of a user through the optical unit. Similarly, in the second display unit, an image emitted from the display portion is seen by the other of the left and right eyes of the user through the optical unit.

Specifically, the optical unit includes a first mirror, a second mirror, a first lens, and a second lens. In the first display unit, the image emitted from the display portion enters the second lens through the first mirror and the second mirror, and then is seen by the one of the left and right eyes of the user. That is, the image emitted from the display portion is reflected by the first mirror and the second mirror in this order, passes through the second lens, and then is seen by the one of the left and right eyes of the user. Note that the image emitted from the display portion passes through the first lens before reaching the second lens. Similarly, in the second display unit, the image emitted from the display portion enters the second lens through the first mirror and the second mirror, and then is seen by the other of the left and right eyes of the user. That is, the image emitted from the display portion is reflected by the first mirror and the second mirror in this order, passes through the second lens, and then is seen by the other of the left and right eyes of the user. Note that the image emitted from the display portion passes through the first lens before reaching the second lens.

In the first display unit, the first mirror is positioned on a normal line passing through the center of gravity of the display portion. The second mirror is positioned on a straight line connecting the centers of two lens surfaces of the second lens. The first lens is positioned on an optical path through which the image emitted from the display portion enters the second lens. The first mirror and the second mirror are preferably placed so that their reflective surfaces are parallel to each other. Note that the same applies to the second display unit.

In one embodiment of the present invention, the first lens functions as a relay lens, and the second lens functions as an eyepiece lens. Such a structure enables a high magnification, i.e., a wide field of view (FOV), which is difficult to achieve with a thin convex lens.

In one embodiment of the present invention, the normal line passing through the center of gravity of the display portion is not aligned with the straight line connecting the centers of the two lens surfaces of the second lens. Such a structure can increase the flexibility in design of the size, definition, resolution, and the like of a display panel including the display portion. As the display panel included in the display device of one embodiment of the present invention, a display with a diagonal size greater than or equal to 0.25 inches and less than or equal to 6 inches can be used, for example. Alternatively, a display with a diagonal size less than 0.25 inches (also referred to as a microdisplay) can also be used. Alternatively, a display with a diagonal size greater than 6 inches can also be used.

In this specification and the like, the center of gravity of a display portion refers to the center of gravity of an external shape (also referred to as an outline) of the display portion in a plan view. Note that in the case where an external shape of a display portion in a plan view is a triangle, a regular polygon, a circle, or an ellipse, the center of the display portion is aligned with the center of gravity of the display portion, and thus the center of gravity of the display portion can sometimes be rephrased as the center of the display portion.

Note that the straight line connecting the centers of the two lens surfaces of the second lens passes through the center of the second lens. Thus, the state where the normal line passing through the center of gravity of the display portion is not aligned with the straight line connecting the centers of the two lens surfaces of the second lens can be rephrased as the state where the center of the second lens is not positioned on the normal line passing through the center of gravity of the display portion.

It is preferable that the first display unit include a first display panel and the first display panel include the display portion included in the first display unit. Similarly, it is preferable that the second display unit include a second display panel and the second display panel include the display portion included in the second display unit.

Note that one display panel may include the display portion included in the first display unit and the display portion included in the second display unit. In other words, the first display unit and the second display unit may include a display panel, and the display panel may include the display portion included in the first display unit and the display portion included in the second display unit. That is, one display panel may display an image for the left eye and an image for the right eye. Such a structure enables one display panel to correspond to the image for the left eye and the image for the right eye. This can reduce the number of display panels, resulting in a reduction in component costs and power consumption. In addition, frame synchronization, optical alignment, image quality adjustment, and the like of the left and right images can be easily performed.

One embodiment of the present invention is an electronic device including the above-described display device, e.g., a binocular display including the above-described display device. The electronic device includes a housing, and the above-described display device is incorporated in the housing.

The housing is fixed by a freely movable arm. Thus, the weight of the housing felt by a user can be reduced as much as possible. In addition, the housing does not need to be provided with a band or the like for fixing the housing to a user's head; thus, the user can easily attach and detach the housing.

The housing is fixed by the arm as described above and thus hardly puts a load on a user's body. Accordingly, as compared with an HMD worn on a user's head, the electronic device of one embodiment of the present invention does not need to be reduced in weight. In addition, a member used for a component of the display device does not need to be reduced in weight. Thus, a metal can also be used for the housing, for example. The use of a metal for the housing can improve dissipation of heat generated in driving the display panel, a circuit board, and the like included in the display device incorporated in the housing. In addition, one or both of the first lens and the second lens can be formed using glass, for example. Thus, a display device and an electronic device that have high display quality can be achieved. In other words, a display device and an electronic device that provide high-quality images to be seen can be achieved.

Note that the housing may be a stationary housing.

### Structure Example 1 of Display Device

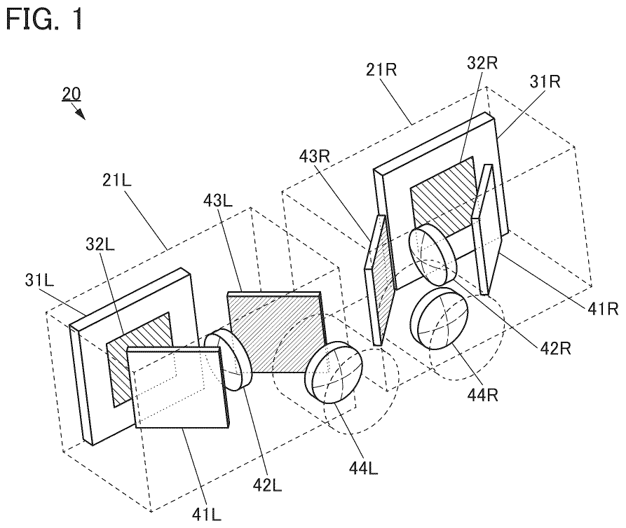

Examples of a structure of a display device that can be used for an electronic device of one embodiment of the present invention will be described with reference to FIG. 1 to FIG. 8B.

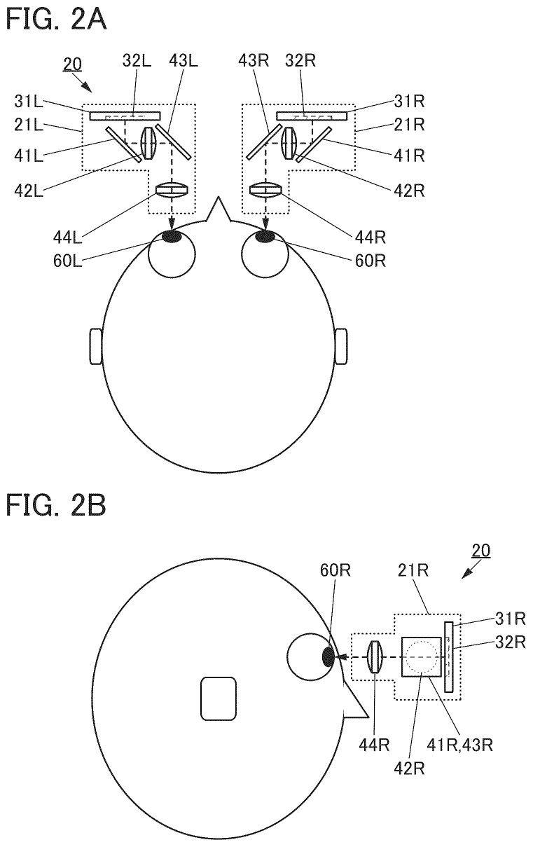

FIG. 1 is a perspective view illustrating the display device. FIG. 2A is a plan view (also referred to as a top view) of the display device, and FIG. 2B is a right side view of the display device. Note that FIG. 2A can also be referred to as a cross-sectional view including an optical path and an optical axis. In each of FIG. 2A and FIG. 2B, part of the optical path is denoted by a dashed line. FIG. 2A illustrates a right eye 60R and a left eye 60L of a user of the display device, and FIG. 2B illustrates the right eye 60R of the user of the display device.

The display device 20 illustrated in FIG. 1, FIG. 2A, and FIG. 2B includes a display unit 21R and a display unit 21L. A pair of left and right display units is composed of the display unit 21R and the display unit 21L. Here, the display unit 21R is a display unit for the right eye, and the display unit 21L is a display unit for the left eye.

In the following description, in the case where items common to components which are distinguished with use of alphabets, such as the display unit 21R and the display unit 21L, are described, a reference numeral without the alphabet is used in some cases.

The display unit 21R includes a display portion 32R, a mirror 41R, a lens 42R, a mirror 43R, and a lens 44R. Similarly, the display unit 21L includes a display portion 32L, a mirror 41L, a lens 42L, a mirror 43L, and a lens 44L. An image emitted from the display portion 32R enters the lens 44R through the mirror 41R and the mirror 43R. Similarly, an image emitted from the display portion 32L enters the lens 44L through the mirror 41L and the mirror 43L. The user can see the image when bringing the eyes near the lens 44R and the lens 44L that are included in the display device 20. Note that the mirror 41R, the lens 42R, the mirror 43R, and the lens 44R may be collectively referred to as an optical unit for the right eye. The mirror 41L, the lens 42L, the mirror 43L, and the lens 44L may be collectively referred to as an optical unit for the left eye.

The mirror 41R is positioned on a normal line passing through the center of gravity of the display portion 32R. The mirror 43R is positioned on a straight line connecting the centers of two lens surfaces of the lens 44R. Similarly, the mirror 41L is positioned on a normal line passing through the center of gravity of the display portion 32L. The mirror 43L is positioned on a straight line connecting the centers of two lens surfaces of the lens 44L.

The lens 42R is positioned on an optical path through which the image emitted from the display portion 32R enters the lens 44R. Similarly, the lens 42L is positioned on an optical path through which the image emitted from the display portion 32L enters the lens 44L. Note that in the display device 20 illustrated in FIG. 1, FIG. 2A, and FIG. 2B, the lens 42R is positioned between the mirror 41R and the mirror 43R, and the lens 42L is positioned between the mirror 41L and the mirror 43L.

In the display device 20 illustrated in FIG. 1, FIG. 2A, and FIG. 2B, the display unit 21R includes a display panel 31R, and the display panel 31R includes the display portion 32R. The display panel 31R is placed so that the front side of the center of the display portion 32R is positioned on the outer corner side of the right eye 60R. Similarly, the display unit 21L includes a display panel 31L, and the display panel 31L includes the display portion 32L. The display panel 31L is placed so that the front side of the center of the display portion 32L is positioned on the outer corner side of the left eye 60L.

The image emitted from the display portion 32R is reflected by the mirror 41R and the mirror 43R in this order, passes through the lens 44R, and then is seen by the right eye 60R. Moreover, the image emitted from the display portion 32R passes through the lens 42R before reaching the lens 44R. Similarly, the image emitted from the display portion 32L is reflected by the mirror 41L and the mirror 43L in this order, passes through the lens 44L, and then is seen by the left eye 60L. Moreover, the image emitted from the display portion 32L passes through the lens 42L before reaching the lens 44L.

In the display device 20 illustrated in FIG. 1, FIG. 2A, and FIG. 2B, the image emitted from the display portion 32R is reflected by the mirror 41R, passes through the lens 42R, is reflected by the mirror 43R, passes through the lens 44R, and then is seen by the right eye 60R. Similarly, the image emitted from the display portion 32L is reflected by the mirror 41L, passes through the lens 42L, is reflected by the mirror 43L, passes through the lens 44L, and then is seen by the left eye 60L.

With use of the mirror 41R and the mirror 43R, the normal line passing through the center of gravity of the display portion 32R (the dashed line from the display portion 32R to the mirror 41R) can be shifted from the straight line connecting the centers of the two lens surfaces of the lens 44R (the dashed line connecting the right eye 60R, the lens 44R, and the mirror 43R). In other words, the normal line passing through the center of gravity of the display portion 32R is not aligned with the straight line connecting the centers of the two lens surfaces of the lens 44R. In particular, in FIG. 2A and FIG. 2B, the normal line passing through the center of gravity of the display portion 32R is parallel to the straight line connecting the centers of the two lens surfaces of the lens 44R. Similarly, the normal line passing through the center of gravity of the display portion 32L is not aligned with the straight line connecting the centers of the two lens surfaces of the lens 44L. In particular, in FIG. 2A and FIG. 2B, the normal line passing through the center of gravity of the display portion 32L is parallel to the straight line connecting the centers of the two lens surfaces of the lens 44L.

Note that the term “parallel” indicates a state where the angle formed between two straight lines is greater than or equal to −5° and less than or equal to 5°. For example, one of the two straight lines refers to the straight line connecting the centers of the two lens surfaces of the lens 44, and the other refers to a straight line perpendicular to the display portion 32 (a display surface of the display portion 32). The term “perpendicular” indicates a state where the angle formed between two straight lines is greater than or equal to 85° and less than or equal to 95°. Alternatively, the term “perpendicular” indicates a state where the angle formed between one straight line and one plane is greater than or equal to 85° and less than or equal to 95°. Alternatively, the term “perpendicular” indicates a state where the angle formed between two planes is greater than or equal to 85° and less than or equal to 95°.

The above-described structure can increase the flexibility in design of the size, definition, resolution, and the like of the display panel. For example, the display panel does not need to be reduced in size. In addition, display panels with different sizes can be used. Thus, the display panel of the display device 20 can be replaced without replacement of the optical unit. Accordingly, even in the case where a defect occurs in one of the display panels, the display device can be used by replacing the one of the display panels.

Although the display portion 32 is illustrated as a square in FIG. 1, there is no particular limitation on the screen ratio (aspect ratio) of the display portion 32. For example, the display portion 32 is compatible with a variety of screen ratios such as 1:1 (a square), 4:3, 16:9, and 16:10. There is no particular limitation on the external shape of the display portion 32, and a variety of shapes such as a square, a rectangle, and a circle can be employed.

As illustrated in FIG. 2A and FIG. 2B, in order to make the normal line passing through the center of gravity of the display portion 32R parallel to the straight line connecting the centers of the two lens surfaces of the lens 44R, the mirror 41R and the mirror 43R are preferably placed so that their reflective surfaces are parallel to each other. Similarly, in order to make the normal line passing through the center of gravity of the display portion 32L parallel to the straight line connecting the centers of the two lens surfaces of the lens 44L, the mirror 41L and the mirror 43L are preferably placed so that their reflective surfaces are parallel to each other.

In FIG. 2A and FIG. 2B, the normal line passing through the center of gravity of the display portion 32R, the straight line connecting the centers of the two lens surfaces of the lens 44R, the normal line passing through the center of gravity of the display portion 32L, and the straight line connecting the centers of the two lens surfaces of the lens 44L are parallel to each other.

The lens 44 (the lens 44R and the lens 44L) is an optical system placed on the side close to the eye and thus functions as an eyepiece lens.

The lens 42 (the lens 42R and the lens 42L) functions as a relay lens. The relay lens is an optical system that transfers an image and plays a role in gathering light, which enters the lens from the image, to form an image on an image plane of a subsequent optical system.

The provision of the lens 42R functioning as a relay lens between the display portion 32R and the lens 44R enables high-magnification observation of the image from the display portion 32R. Similarly, the provision of the lens 42L functioning as a relay lens between the display portion 32L and the lens 44L enables high-magnification observation of the image from the display portion 32L.

When the lens 42 functioning as a relay lens is provided, the user sees the image while a viewing angle is widened, and thus can obtain a sense of immersion and a realistic sensation. In addition, since the display panel has high design flexibility as described above, application of a high-resolution display panel can achieve both a large viewing angle and high angular resolution, for example.

A convex lens can be used as each of the lens 42 and the lens 44. Although FIG. 1, FIG. 2A, and FIG. 2B show an example in which a biconvex lens is used as each of the lens 42 and the lens 44, the present invention is not limited thereto. For example, the lens 42 and the lens 44 may each be formed of one or more plano-convex lenses. Alternatively, the lens 42 and the lens 44 can each be formed by combining a plurality of lenses selected from a biconvex lens, a plano-convex lens, a biconcave lens, a plano-concave lens, a convex meniscus lens, and a concave meniscus lens. Furthermore, a lens other than the lens 42 and the lens 44 may be provided.

In FIG. 2A and FIG. 2B, the display panel 31R is placed so that the front side of the center of the display portion 32R is positioned on the outer corner side of the right eye 60R, and the display panel 31L is placed so that the front side of the center of the display portion 32L is positioned on the outer corner side of the left eye 60L. Note that the present invention is not limited thereto.

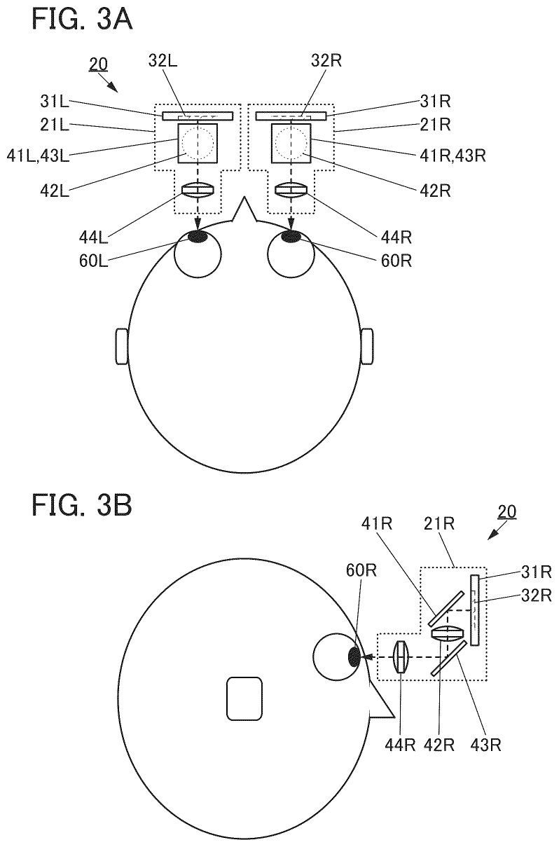

Another structure example of the display device of one embodiment of the present invention will be described with reference to FIG. 3A and FIG. 3B. FIG. 3A is a plan view of the display device 20, and FIG. 3B is a right side view of the display device. Note that FIG. 3B can also be referred to as a cross-sectional view including an optical path and an optical axis. In each of FIG. 3A and FIG. 3B, part of the optical path is denoted by a dashed line.

The display device 20 illustrated in FIG. 3A and FIG. 3B is a modification example of the display device 20 illustrated in FIG. 2A and FIG. 2B. Specifically, the display device 20 illustrated in FIG. 3A and FIG. 3B is different from the display device 20 illustrated in FIG. 2A and FIG. 2B in the arrangement of the display panel 31R and the display panel 31L. Hereinafter, the contents already described with reference to FIG. 2A and FIG. 2B are referred to for portions common to the contents, and the description of the portions is omitted.

As illustrated in FIG. 3A and FIG. 3B, for example, the display panel 31R may be placed so that the front side of the center of the display portion 32R is positioned above the right eye 60R, and the display panel 31L may be placed so that the front side of the center of the display portion 32L is positioned above the left eye 60L. Also in the structure illustrated in FIG. 3A and FIG. 3B, the normal line passing through the center of gravity of the display portion 32R is parallel to the straight line connecting the centers of the two lens surfaces of the lens 44R, and the normal line passing through the center of gravity of the display portion 32L is parallel to the straight line connecting the centers of the two lens surfaces of the lens 44L.

Note that the display panel is not necessarily placed on the outer corner side of the eye or above the eye; for example, the display panel 31R may be placed so that the front side of the center of the display portion 32R is positioned below the right eye 60R, and the display panel 31L may be placed so that the front side of the center of the display portion 32L is positioned below the left eye 60L.

In FIG. 2A and FIG. 2B, the display panel 31R is placed on a side farther from the user than the mirror 41R is, and the display panel 31L is placed on a side farther from the user than the mirror 41L is. The same applies to the structure illustrated in FIG. 3A and FIG. 3B. Note that the arrangement of the mirror 41 and the mirror 43 or the arrangement of the display panels 31 is not limited thereto as long as the normal line passing through the center of gravity of the display portion 32R is shifted from the straight line connecting the centers of the two lens surfaces of the lens 44R and the normal line passing through the center of gravity of the display portion 32L is shifted from the straight line connecting the centers of the two lens surfaces of the lens 44L.

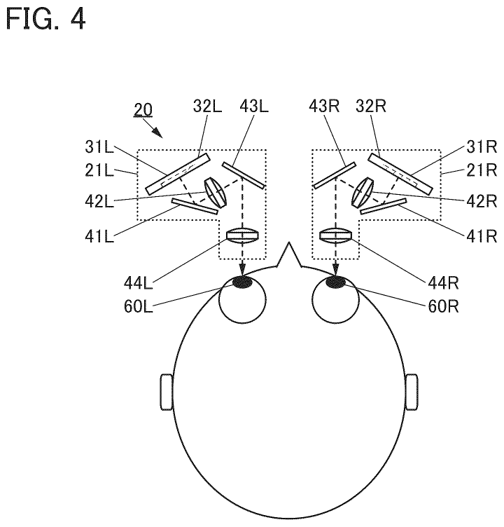

As illustrated in FIG. 4, for example, a reflective surface of the mirror 41R is not necessarily parallel to a reflective surface of the mirror 43R. In that case, the display panel 31R is preferably placed in accordance with the positions of the mirror 41R, the lens 42R, the mirror 43R, and the lens 44R. Similarly, a reflective surface of the mirror 41L is not necessarily parallel to a reflective surface of the mirror 43L.

Alternatively, for example, the display panel 31R may be placed on a side closer to the user than the mirror 41R is, and the display panel 31L may be placed on a side closer to the user than the mirror 41L is. In this case, the angle formed between the reflective surface of the mirror 41R and the reflective surface of the mirror 43R and the angle formed between the reflective surface of the mirror 41L and the reflective surface of the mirror 43L are each preferably less than 180°. For example, the angle formed between the reflective surface of the mirror 41R and the reflective surface of the mirror 43R and the angle formed between the reflective surface of the mirror 41L and the reflective surface of the mirror 43L are each preferably 90°.

FIG. 2A and FIG. 2B illustrate a structure in which the display device 20 includes two display panels (the display panel 31R and the display panel 31L). The same applies to the display device 20 illustrated in FIG. 3A and FIG. 3B. Note that the present invention is not limited thereto. For example, the display device 20 may include one display panel and the display panel may include two display portions.

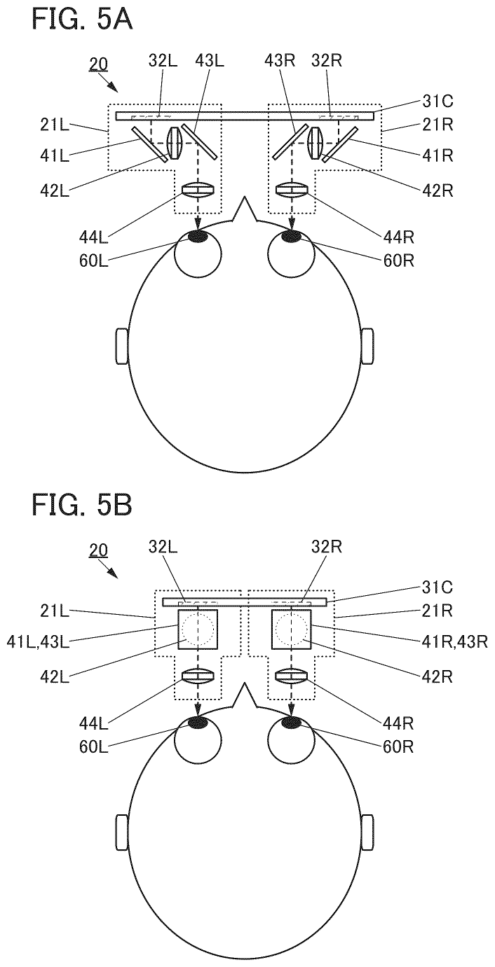

Other structure examples of the display device of one embodiment of the present invention are described with reference to FIG. 5A and FIG. 5B. FIG. 5A and FIG. 5B are plan views of the display device 20. In each of FIG. 5A and FIG. 5B, part of an optical path is denoted by a dashed line.

The display device 20 illustrated in FIG. 5A is a modification example of the display device 20 illustrated in FIG. 2A and FIG. 2B. The display device 20 illustrated in FIG. 5A is different from the display device 20 illustrated in FIG. 2A and FIG. 2B in including one display panel (a display panel 31C) instead of two display panels (the display panel 31R and the display panel 31L). Hereinafter, the contents already described with reference to FIG. 2A and FIG. 2B are referred to for portions common to the contents, and the description of the portions is omitted.

The display device 20 illustrated in FIG. 5A includes the display panel 31C. In other words, the display unit 21R and the display unit 21L include the display panel 31C. The display panel 31C includes the display portion 32R and the display portion 32L.

The display device 20 illustrated in FIG. 5B is a modification example of the display device 20 illustrated in FIG. 3A and FIG. 3B. The display device 20 illustrated in FIG. 5B is different from the display device 20 illustrated in FIG. 3A and FIG. 3B in including one display panel (the display panel 31C) instead of two display panels (the display panel 31R and the display panel 31L). Hereinafter, the contents already described with reference to FIG. 3A and FIG. 3B are referred to for portions common to the contents, and the description of the portions is omitted.

The display device 20 illustrated in FIG. 5B includes the display panel 31C. The display panel 31C includes the display portion 32R and the display portion 32L.

When the display device 20 includes one display panel as illustrated in FIG. 5A and FIG. 5B, the number of display panels can be reduced, resulting in a reduction in component costs and power consumption. In addition, frame synchronization, optical alignment, image quality adjustment, and the like of the left and right images can be easily performed.

In FIG. 2A to FIG. 5B, the lens 42R is placed so as to be positioned between the mirror 41R and the mirror 43R, and the lens 42L is placed so as to be positioned between the mirror 41L and the mirror 43L. Note that the present invention is not limited thereto.

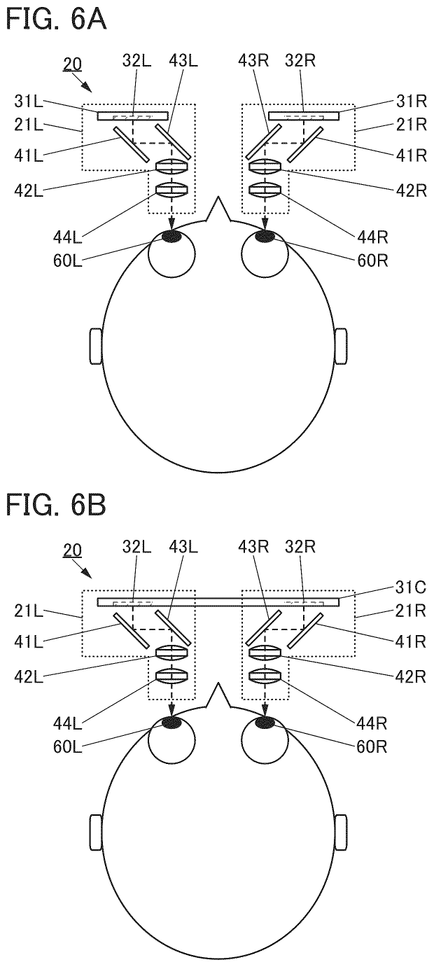

Other structure examples of the display device of one embodiment of the present invention are described with reference to FIG. 6A to FIG. 8B. FIG. 6A and FIG. 6B are plan views of the display device 20. In each of FIG. 6A and FIG. 6B, part of an optical path is denoted by a dashed line.

The display device 20 illustrated in FIG. 6A is a modification example of the display device 20 illustrated in FIG. 2A and FIG. 2B. The display device 20 illustrated in FIG. 6A is different from the display device 20 illustrated in FIG. 2A and FIG. 2B in the arrangement of the lenses 42. Hereinafter, the contents already described with reference to FIG. 2A and FIG. 2B are referred to for portions common to the contents, and the description of the portions is omitted.

The lens 42R is positioned between the mirror 43R and the lens 44R. In this case, an image emitted from the display portion 32R is reflected by the mirror 41R and the mirror 43R in this order, passes through the lens 42R, passes through the lens 44R, and then is seen by the right eye 60R. Note that as in the display device 20 illustrated in FIG. 2A and FIG. 2B, the image emitted from the display portion 32R is reflected by the mirror 41R and the mirror 43R in this order, passes through the lens 44R, and then is seen by the right eye 60R, and the image emitted from the display portion 32R passes through the lens 42R before reaching the lens 44R. Similarly, the lens 42L is positioned between the mirror 43L and the lens 44L. In this case, an image emitted from the display portion 32L is reflected by the mirror 41L and the mirror 43L in this order, passes through the lens 42L, passes through the lens 44L, and then is seen by the left eye 60L. Note that as in the display device 20 illustrated in FIG. 2A and FIG. 2B, the image emitted from the display portion 32L is reflected by the mirror 41L and the mirror 43L in this order, passes through the lens 44L, and then is seen by the left eye 60L, and the image emitted from the display portion 32L passes through the lens 42L before reaching the lens 44L.

With the above-described structure, the distance between the mirror 41R and the mirror 43R can be reduced. In addition, the distance between the mirror 41L and the mirror 43L can be reduced. Thus, the display device 20 can be reduced in size. Moreover, a straight line connecting the centers of two lens surfaces of the lens 42R is aligned with the straight line connecting the centers of the two lens surfaces of the lens 44R, and a straight line connecting the centers of two lens surfaces of the lens 42L is aligned with the straight line connecting the centers of the two lens surfaces of the lens 44L. Therefore, optical alignment can be easily performed.

FIG. 6A illustrates a structure in which the display device 20 includes two display panels. Note that as in the structure illustrated in FIG. 5A, the display device 20 may include one display panel and the display panel may include two display portions (FIG. 6B).

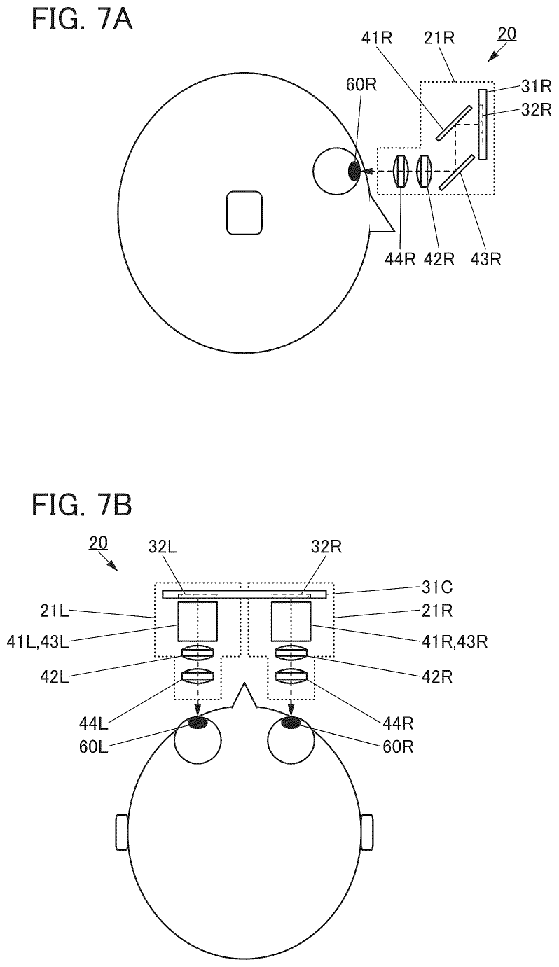

FIG. 7A is a right side view of the display device 20. FIG. 7B is a plan view of the display device 20. In each of FIG. 7A and FIG. 7B, part of an optical path is denoted by a dashed line.

The display device 20 illustrated in FIG. 7A is a modification example of the display device 20 illustrated in FIG. 3A and FIG. 3B. The display device 20 illustrated in FIG. 7A is different from the display device 20 illustrated in FIG. 3A and FIG. 3B in the arrangement of the lenses 42. Hereinafter, the contents already described with reference to FIG. 3A and FIG. 3B are referred to for portions common to the contents, and the description of the portions is omitted.

The lens 42R is positioned between the mirror 43R and the lens 44R. In this case, an image emitted from the display portion 32R is reflected by the mirror 41R and the mirror 43R in this order, passes through the lens 42R, passes through the lens 44R, and then is seen by the right eye 60R. Similarly, the lens 42L is positioned between the mirror 43L and the lens 44L. In this case, an image emitted from the display portion 32L is reflected by the mirror 41L and the mirror 43L in this order, passes through the lens 42L, passes through the lens 44L, and then is seen by the left eye 60L.

With the above-described structure, the distance between the mirror 41R and the mirror 43R can be reduced. In addition, the distance between the mirror 41L and the mirror 43L can be reduced. Thus, the display device 20 can be reduced in size. Moreover, the straight line connecting the centers of the two lens surfaces of the lens 42R is aligned with the straight line connecting the centers of the two lens surfaces of the lens 44R, and the straight line connecting the centers of the two lens surfaces of the lens 42L is aligned with the straight line connecting the centers of the two lens surfaces of the lens 44L. Therefore, optical alignment can be easily performed.

FIG. 7A illustrates a structure in which the display device 20 includes two display panels. Note that as in the structure illustrated in FIG. 5B, the display device 20 may include one display panel and the display panel may include two display portions (FIG. 7B).

As described above, when the lens 42 is placed between the mirror 43 and the lens 44, the distance between the mirror 41 and the mirror 43 can be reduced. Thus, in some cases, the display portion 32 can be placed so that the front side of the center of the display portion 32 is positioned on the inner corner side of the eye, for example.

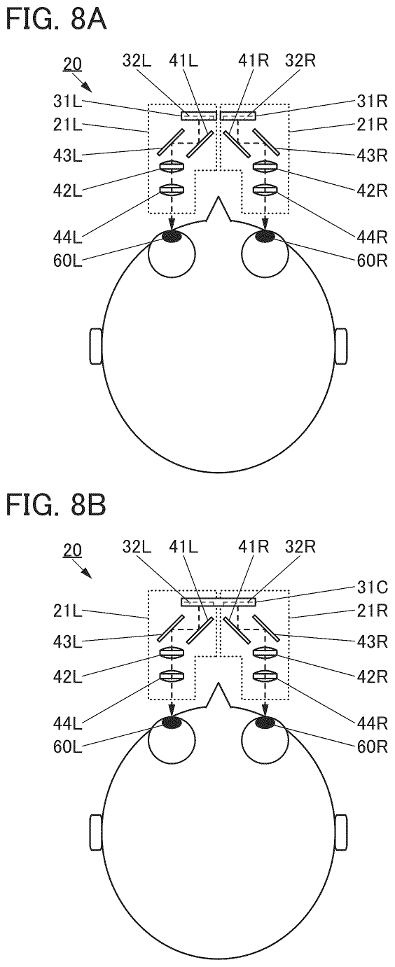

FIG. 8A and FIG. 8B are plan views of the display device 20. In each of FIG. 8A and FIG. 8B, part of an optical path is denoted by a dashed line.

The display device 20 illustrated in FIG. 8A is a modification example of the display device 20 illustrated in FIG. 6A. The display device 20 illustrated in FIG. 8A is different from the display device 20 illustrated in FIG. 6A in the arrangement of the display portions 32. Hereinafter, the contents already described with reference to FIG. 6A are referred to for portions common to the contents, and the description of the portions is omitted.

The display panel 31R is placed so that the front side of the center of the display portion 32R is positioned on the inner corner side of the right eye 60R. Similarly, the display panel 31L is placed so that the front side of the center of the display portion 32L is positioned on the inner corner side of the left eye 60L.

With the above-described structure, the distance between the display panel 31R and the display panel 31L can be reduced. Thus, the display device 20 can be reduced in size.

FIG. 8A illustrates a structure in which the display device 20 includes two display panels. Note that as in the structure illustrated in FIG. 6B, the display device 20 may include one display panel and the display panel may include two display portions (FIG. 8B).

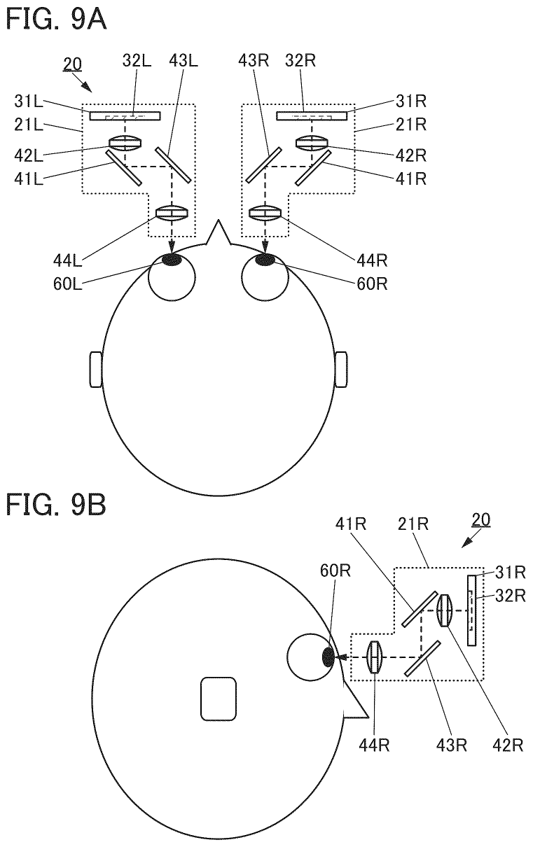

Another structure example of the display device of one embodiment of the present invention will be described with reference to FIG. 9A and FIG. 9B. FIG. 9A is a plan view of the display device 20. FIG. 9B is a right side view of the display device 20. In each of FIG. 9A and FIG. 9B, part of an optical path is denoted by a dashed line.

The display device 20 illustrated in FIG. 9A is a modification example of the display device 20 illustrated in FIG. 2A and FIG. 2B. The display device 20 illustrated in FIG. 9A is different from the display device 20 illustrated in FIG. 2A and FIG. 2B in the arrangement of the lenses 42. Hereinafter, the contents already described with reference to FIG. 2A and FIG. 2B are referred to for portions common to the contents, and the description of the portions is omitted.

The lens 42R is positioned between the display portion 32R and the mirror 41R. In this case, an image emitted from the display portion 32R passes through the lens 42R, is reflected by the mirror 41R and the mirror 43R in this order, passes through the lens 44R, and then is seen by the right eye 60R. Similarly, the lens 42L is positioned between the display portion 32L and the mirror 41L. In this case, an image emitted from the display portion 32L passes through the lens 42L, is reflected by the mirror 41L and the mirror 43L in this order, passes through the lens 44L, and then is seen by the left eye 60L.

With the above-described structure, the distance between the mirror 41R and the mirror 43R can be reduced. In addition, the distance between the mirror 41L and the mirror 43L can be reduced. Thus, the display device 20 can be reduced in size in some cases.

FIG. 9A illustrates a structure in which the display device 20 includes two display panels. Note that as in the structure illustrated in FIG. 5A, the display device 20 may include one display panel and the display panel may include two display portions.

The display device 20 illustrated in FIG. 9B is a modification example of the display device 20 illustrated in FIG. 3A and FIG. 3B. The display device 20 illustrated in FIG. 9B is different from the display device 20 illustrated in FIG. 3A and FIG. 3B in the arrangement of the lenses 42. Hereinafter, the contents already described with reference to FIG. 3A and FIG. 3B are referred to for portions common to the contents, and the description of the portions is omitted.

The lens 42R is positioned between the display portion 32R and the mirror 41R. The description on the optical path in this case is similar to that in FIG. 9A and is omitted here. Similarly, the lens 42L is positioned between the display portion 32L and the mirror 41L. The description on the optical path in this case is similar to that in FIG. 9A and is omitted here.

With the above-described structure, the distance between the mirror 41R and the mirror 43R can be reduced. In addition, the distance between the mirror 41L and the mirror 43L can be reduced. Thus, the display device 20 can be reduced in size. Moreover, the straight line connecting the centers of the two lens surfaces of the lens 42R is aligned with the straight line connecting the centers of the two lens surfaces of the lens 44R, and the straight line connecting the centers of the two lens surfaces of the lens 42L is aligned with the straight line connecting the centers of the two lens surfaces of the lens 44L. Therefore, optical alignment can be easily performed.

FIG. 9B illustrates a structure in which the display device 20 includes two display panels. Note that as in the structure illustrated in FIG. 5B, the display device 20 may include one display panel and the display panel may include two display portions.

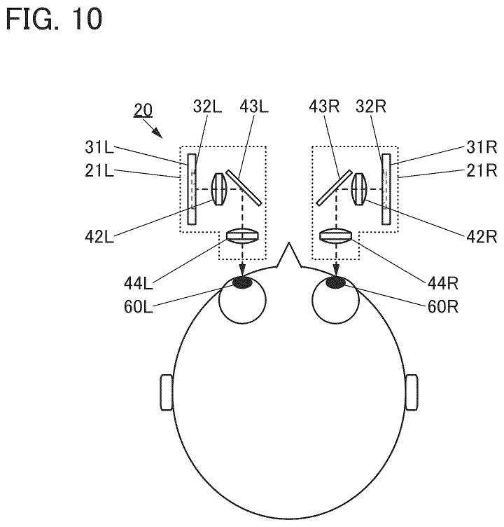

Although FIG. 2A to FIG. 9B each illustrate a structure in which the display unit includes two mirrors, the present invention is not limited thereto. For example, as illustrated in FIG. 10, the display unit may include one mirror.

In FIG. 10, the display unit 21R includes the lens 42R, the mirror 43R, and the lens 44R. Similarly, the display unit 21L includes the lens 42L, the mirror 43L, and the lens 44L. In the structure illustrated in FIG. 10, an image emitted from the display portion 32R passes through the lens 42R, is reflected by the mirror 43R, passes through the lens 44R, and then is seen by the right eye 60R. Similarly, an image emitted from the display portion 32L passes through the lens 42L, is reflected by the mirror 43L, passes through the lens 44L, and then is seen by the left eye 60L.

With the above-described structure, the number of components of the display device can be reduced and the weight of the display device can be reduced.

Note that although the lens 42 is placed between the display portion 32 and the mirror 43 in FIG. 10, the present invention is not limited thereto. The lens 42 may be placed between the mirror 43 and the lens 44.

As a display panel that can be used for the display device 20, a liquid crystal panel including a liquid crystal element, an organic EL panel including an organic EL element, an LED panel including a micro LED, or the like can be used. In particular, an organic EL panel is preferably used because a self-luminous and high-definition display portion is easily formed. In this specification and the like, a light-emitting diode whose chip area is less than or equal to 10000 μm² is referred to as a micro LED. Note that without limitation to the micro LED, a light-emitting diode whose chip area is greater than 10000 μm² and less than or equal to 1 mm² (also referred to as a mini LED) may be used for the LED panel, for example.

### Structure Example 2 of Display Device

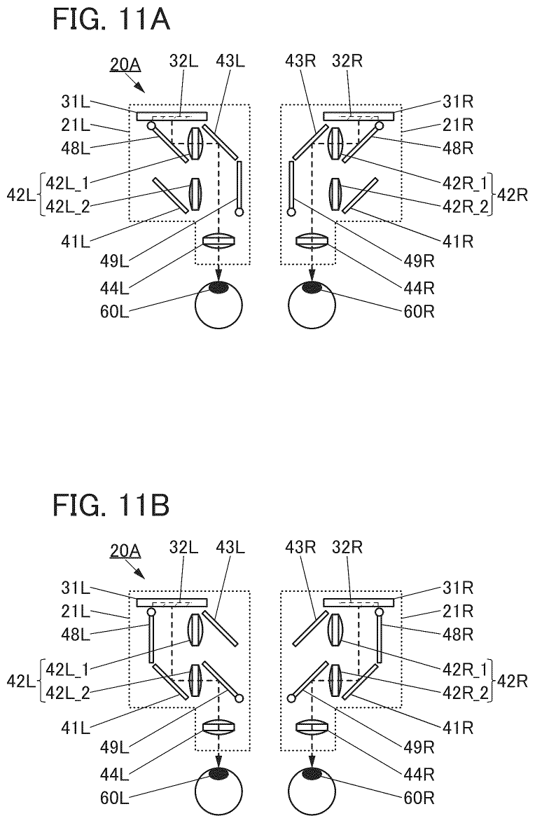

Other examples of a structure of a display device that can be used for an electronic device of one embodiment of the present invention will be described with reference to FIG. 11A to FIG. 13B.

FIG. 11A and FIG. 11B are plan views of a display device 20A. Note that FIG. 11A and FIG. 11B can each also be referred to as a cross-sectional view including an optical path and an optical axis. In each of FIG. 11A and FIG. 11B, part of the optical path is denoted by a dashed line.

Like the display device 20 described in <Structure example 1 of display device> above, the display device 20A illustrated in FIG. 11A and FIG. 11B includes the display unit 21R and the display unit 21L. The display unit 21R includes the display portion 32R, the mirror 41R, the lens 42R, the mirror 43R, and the lens 44R. The display unit 21L includes the display portion 32L, the mirror 41L, the lens 42L, the mirror 43L, and the lens 44L. The user can see the image when bringing the eyes near the lens 44R and the lens 44L that are included in the display device 20A.

The display unit 21R further includes a mirror 48R and a mirror 49R. As the lens 42R, two lenses (a lens 42R_1 and a lens 42R_2) are provided. Similarly, the display unit 21L further includes a mirror 48L and a mirror 49L. As the lens 42L, two lenses (a lens 42L_1 and a lens 42L_2) are provided.

The mirror 41R is positioned on the normal line passing through the center of gravity of the display portion 32R. The mirror 48R is provided between the mirror 41R and the display portion 32R. Similarly, the mirror 41L is positioned on the normal line passing through the center of gravity of the display portion 32L. The mirror 48L is provided between the mirror 41L and the display portion 32L.

The mirror 43R is positioned on the straight line connecting the centers of the two lens surfaces of the lens 44R. The mirror 49R is provided between the mirror 43R and the lens 44R. Similarly, the mirror 43L is positioned on the straight line connecting the centers of the two lens surfaces of the lens 44L. The mirror 49L is provided between the mirror 43L and the lens 44L.

The lens 42R_1 is positioned between the mirror 48R and the mirror 43R. The lens 42R_2 is positioned between the mirror 41R and the mirror 49R. Similarly, the lens 42L_1 is positioned between the mirror 48L and the mirror 43L. The lens 42L_2 is positioned between the mirror 41L and the mirror 49L.

The lens 42R 1 and the lens 42R_2 differ in the magnification ratio, for example. Similarly, the lens 42L_1 and the lens 42L_2 differ in the magnification ratio, for example.

The mirror 48 and the mirror 49 each preferably have a mechanism for changing its position or orientation. For example, the mirror 48 and the mirror 49 each preferably have a mechanism capable of one or both of translational movement and rotational movement.

The mirror 48 and the mirror 49 that are illustrated in FIG. 11A and FIG. 11B each have a mechanism capable of rotational movement. Specifically, the mirror 48 and the mirror 49 each have a mechanism capable of rotational movement with the direction perpendicular to the plane including the optical path as the axis.

FIG. 11A illustrates, as an example, a structure in which the mirror 49R is not positioned on the straight line connecting the centers of the two lens surfaces of the lens 44R, and the mirror 49L is not positioned on the straight line connecting the centers of the two lens surfaces of the lens 44L. In this case, an image emitted from the display portion 32R enters the lens 44R through the mirror 48R, the lens 42R_1, and the mirror 43R, and then is seen by the right eye 60R. Specifically, the image emitted from the display portion 32R is reflected by the mirror 48R, passes through the lens 42R_1, is reflected by the mirror 43R, passes through the lens 44R, and then is seen by the right eye 60R. Similarly, an image emitted from the display portion 32L enters the lens 44L through the mirror 48L, the lens 42L_1, and the mirror 43L, and then is seen by the left eye 60L. Specifically, the image emitted from the display portion 32L is reflected by the mirror 48L, passes through the lens 42L_1, is reflected by the mirror 43L, passes through the lens 44L, and then is seen by the left eye 60L.

FIG. 11B illustrates, as an example, a structure in which the mirror 49R is positioned on the straight line connecting the centers of the two lens surfaces of the lens 44R, and the mirror 49L is positioned on the straight line connecting the centers of the two lens surfaces of the lens 44L. In this case, an image emitted from the display portion 32R enters the lens 44R through the mirror 41R, the lens 42R_2, and the mirror 49R, and then is seen by the right eye 60R. Specifically, the image emitted from the display portion 32R is reflected by the mirror 41R, passes through the lens 42R_2, is reflected by the mirror 49R, passes through the lens 44R, and then is seen by the right eye 60R. Similarly, an image emitted from the display portion 32L enters the lens 44L through the mirror 41L, the lens 42L_2, and the mirror 49L, and then is seen by the left eye 60L. Specifically, the image emitted from the display portion 32L is reflected by the mirror 41L, passes through the lens 42L_2, is reflected by the mirror 49L, passes through the lens 44L, and then is seen by the left eye 60L.

As described above, when the mirror 48 and the mirror 49 each have the mechanism capable of rotational movement, the optical path can be changed. In other words, the lens 42 can be selected. With such a structure, a more appropriate lens can be prepared in advance as compared with the case where the magnification ratio is changed by moving the position of a lens.

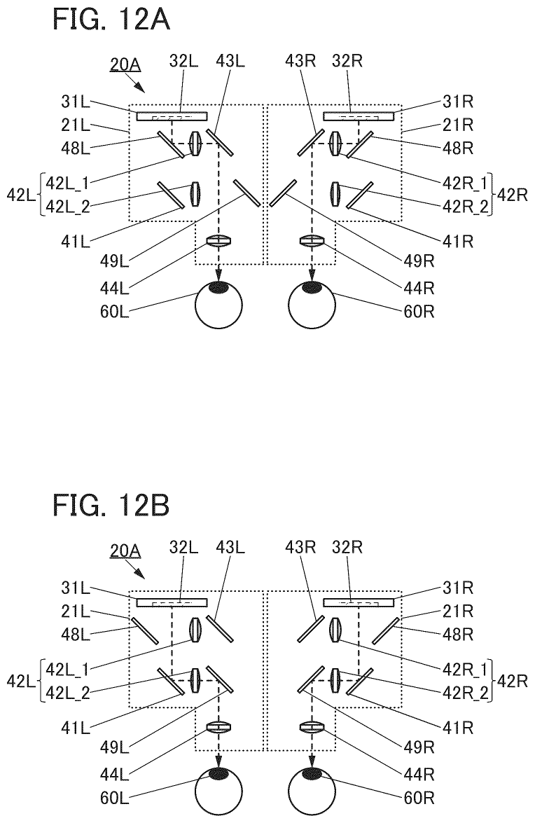

FIG. 12A and FIG. 12B are plan views of the display device 20A. Note that FIG. 12A and FIG. 12B can each also be referred to as a cross-sectional view including an optical path and an optical axis. In each of FIG. 12A and FIG. 12B, part of the optical path is denoted by a dashed line.

The display device 20A illustrated in FIG. 12A and FIG. 12B includes the mirror 48 and the mirror 49 each having a mechanism capable of translational movement. In the display device 20A illustrated in FIG. 12A and FIG. 12B, the mirror 48 and the mirror 49 each have a mechanism capable of translational movement in a plane direction including the optical path.

FIG. 12A illustrates, as an example, a structure in which the mirror 49R is not positioned on the straight line connecting the centers of the two lens surfaces of the lens 44R, and the mirror 49L is not positioned on the straight line connecting the centers of the two lens surfaces of the lens 44L. The description on the optical path in this case is similar to that in FIG. 11A and is omitted here.

FIG. 12B illustrates, as an example, a structure in which the mirror 49R is positioned on the straight line connecting the centers of the two lens surfaces of the lens 44R, and the mirror 49L is positioned on the straight line connecting the centers of the two lens surfaces of the lens 44L. The description on the optical path in this case is similar to that in FIG. 11B and is omitted here.

As described above, when the mirror 48 and the mirror 49 each have the mechanism capable of translational movement, the optical path can be changed. In other words, the lens 42 can be selected. With such a structure, a more appropriate lens can be prepared in advance as compared with the case where the magnification ratio is changed by moving the position of a lens.

Note that when the mirror 48 and the mirror 49 each have the mechanism capable of translational movement, the display unit (optical unit) does not necessarily include the mirror 41 and the mirror 43 in some cases.

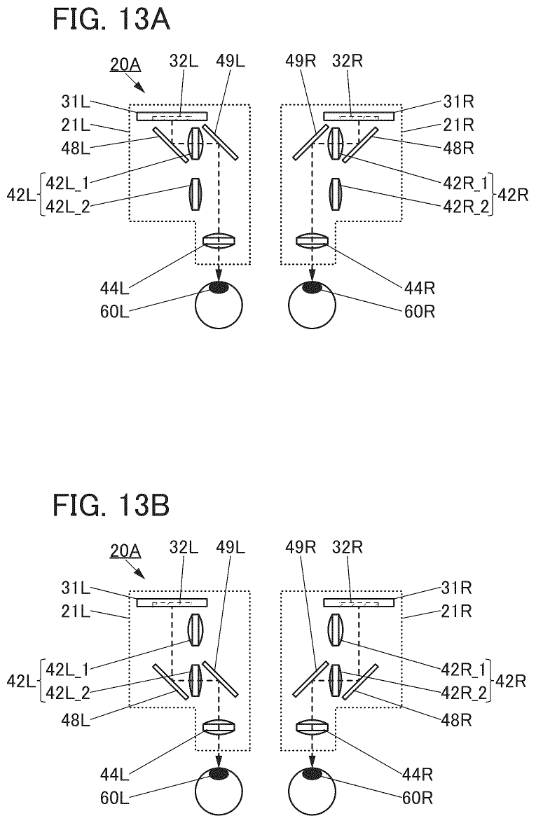

FIG. 13A and FIG. 13B are plan views of the display device 20A. Note that FIG. 13A and FIG. 13B can each also be referred to as a cross-sectional view including an optical path and an optical axis. In each of FIG. 13A and FIG. 13B, part of the optical path is denoted by a dashed line.

The display device 20A illustrated in FIG. 13A and FIG. 13B is a modification example of the display device 20A illustrated in FIG. 12A and FIG. 12B. The display device 20A illustrated in FIG. 13A and FIG. 13B is different from the display device 20A illustrated in FIG. 12A and FIG. 12B in not including the mirror 41 and the mirror 43. Hereinafter, the contents already described with reference to FIG. 12A and FIG. 12B are referred to for portions common to the contents, and the description of the portions is omitted.

As in the display device 20A illustrated in FIG. 12A and FIG. 12B, the mirror 48 and the mirror 49 each have a mechanism capable of translational movement in a plane direction including the optical path.

FIG. 13A illustrates, as an example, a structure in which the mirror 48R and the mirror 49R are positioned so that the lens 42R_1 is interposed therebetween, and the mirror 48L and the mirror 49L are positioned so that the lens 42L_1 is interposed therebetween. In this case, an image emitted from the display portion 32R is reflected by the mirror 48R, passes through the lens 42R_1, is reflected by the mirror 49R, passes through the lens 44R, and then is seen by the right eye 60R. Similarly, an image emitted from the display portion 32L is reflected by the mirror 48L, passes through the lens 42L_1, is reflected by the mirror 49L, passes through the lens 44L, and then is seen by the left eye 60L.

FIG. 13B illustrates, as an example, a structure in which the mirror 48R and the mirror 49R are positioned so that the lens 42R_2 is interposed therebetween, and the mirror 48L and the mirror 49L are positioned so that the lens 42L_2 is interposed therebetween. The description on the optical path in this case is similar to that in FIG. 13A and is omitted here.

As described above, when the mirror 48 and the mirror 49 each have the mechanism capable of translational movement, the optical path can be changed. In other words, the lens 42 can be selected. With such a structure, a more appropriate lens can be prepared in advance as compared with the case where the magnification ratio is changed by moving the position of a lens. Moreover, the number of components of the display device can be reduced and the weight of the display device can be reduced.

Although two lenses are provided as the lens 42 in FIG. 11A to FIG. 13B, the present invention is not limited thereto. For example, three or more lenses may be provided as the lens 42. In this case, for the display devices illustrated in FIG. 11A to FIG. 12B, the number of mirrors to be prepared (the mirror 48 and the mirror 49) each having a mechanism for changing its position or orientation is preferably the same as the number of lenses to be provided as the lens 42.

FIG. 11A to FIG. 13B illustrate the structures in each of which the display unit 21R includes the display panel 31R, the display panel 31R includes the display portion 32R, the display unit 21L includes the display panel 31L, and the display panel 31L includes the display portion 32L. Note that the present invention is not limited thereto. For example, as in the structure illustrated in FIG. 5A, the display unit 21R and the display unit 21L may include one display panel, and the display panel may include the display portion 32R and the display portion 32L.

Although the display panel included in the display device 20A is placed on the outer corner side of the eye in FIG. 11A to FIG. 13B, the present invention is not limited thereto. For example, as in the structure illustrated in FIG. 3A and FIG. 3B, the display panel included in the display device 20A may be placed above the eye.

### Structure Example 3 of Display Device

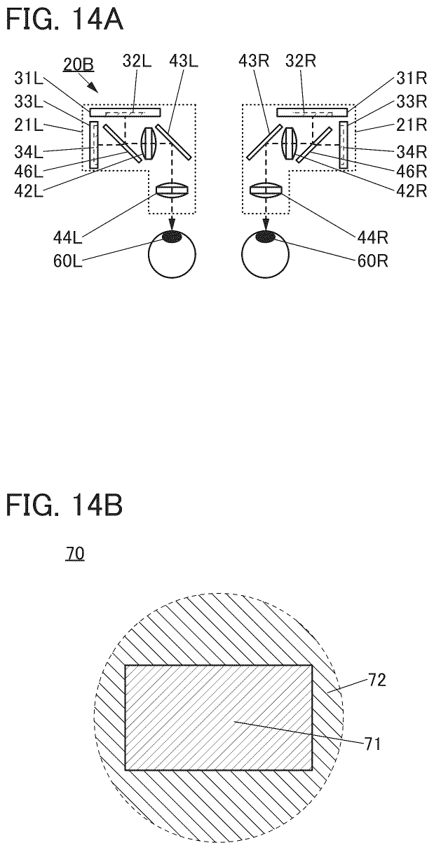

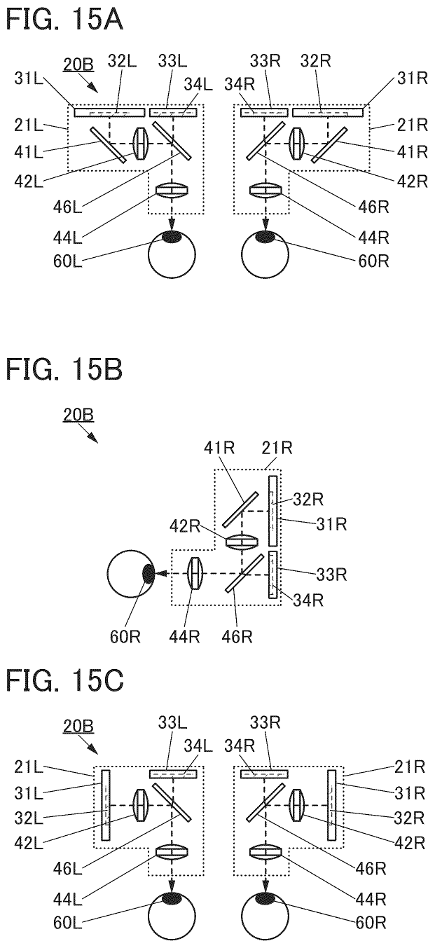

Other examples of a structure of a display device that can be used for an electronic device of one embodiment of the present invention will be described with reference to FIG. 14A to FIG. 15C.

FIG. 14A is a plan view of a display device 20B. Note that FIG. 14A can also be referred to as a cross-sectional view including an optical path and an optical axis. In FIG. 14A, part of the optical path is denoted by a dashed line.

The display device 20B illustrated in FIG. 14A is different from the display device 20 illustrated in FIG. 2A and FIG. 2B in including a half mirror 46 instead of the mirror 41 and in further including two display portions. Hereinafter, the contents already described with reference to FIG. 2A and FIG. 2B are referred to for portions common to the contents, and the description of the portions is omitted.

Like the display device 20 described in <Structure example 1 of display device> above, the display device 20B illustrated in FIG. 14A includes the display unit 21R and the display unit 21L. The display unit 21R includes the display portion 32R, the lens 42R, the mirror 43R, and the lens 44R. The display unit 21L includes the display portion 32L, the lens 42L, the mirror 43L, and the lens 44L. The user can see the image when bringing the eyes near the lens 44R and the lens 44L that are included in the display device 20B.

The display unit 21R includes a half mirror 46R instead of the mirror 41R. Similarly, the display unit 21L includes a half mirror 46L instead of the mirror 41L.

The display unit 21R further includes a display panel 33R, and the display panel 33R includes a display portion 34R. The display panel 33R is placed so as to be positioned on the outer corner side of the right eye 60R. Similarly, the display unit 21L further includes a display panel 33L, and the display panel 33L includes a display portion 34L. The display panel 33L is placed so as to be positioned on the outer corner side of the left eye 60L.

That is, the display unit 21R includes two display panels. In addition, the display unit 21R includes two display portions. Similarly, the display unit 21L includes two display panels. In addition, the display unit 21L includes two display portions.

The display portion 34R and the lens 42R are positioned to face each other with the half mirror 46R therebetween. Similarly, the display portion 34L and the lens 42L are positioned to face each other with the half mirror 46L therebetween.

The half mirror 46 can have a structure in which, for example, optical glass with high visible light transmittance is used as a base and a surface provided with a metal film or a dielectric film is used as a reflective surface. The visible light transmittance and the visible light reflectance of the half mirror 46 can each be approximately 50 %, for example. Note that the half mirror 46 may be configured to have higher transmittance than reflectance (transmittance>reflectance) or higher reflectance than transmittance (transmittance<reflectance) in view of the luminance and the like of each display panel.

The display panel 33, which is a display panel with a relatively small screen size and a high pixel density, corresponds to the central field of view. Note that the pixel density of the display panel 33 is higher than the pixel density of the display panel 31.

An image emitted from the display portion 32R is reflected by a reflective surface of the half mirror 46R and then enters the lens 42R. An image emitted from the display portion 34R passes through the half mirror 46R and then enters the lens 42R. Similarly, an image emitted from the display portion 32L is reflected by a reflective surface of the half mirror 46L and then enters the lens 42L. An image emitted from the display portion 34L passes through the half mirror 46L and then enters the lens 42L.

In order that an image emitted from the display portion 32 can enter the lens 42 facing the display portion 34, each component is preferably provided so as to avoid interference. For example, each component can be placed so that the angle formed between the reflective surface of the half mirror 46 and the display surface of the display portion 32 and the angle formed between the reflective surface of the half mirror 46 and a display surface of the display portion 34 are each greater than or equal to 35° and less than or equal to 55°, preferably greater than or equal to 40° and less than or equal to 50°. Typically, each component is preferably placed so that the angle is approximately 45°.

Next, the synthesis of images is described. FIG. 14A illustrates part of an optical path at the time when an image emitted from the display portion 32 is seen and part of an optical path at the time when an image emitted from the display portion 34 is seen.

An image emitted from the display portion 32R is reflected by the half mirror 46R and then enters the lens 42R. Next, the image emitted from the display portion 32R and then condensed by the lens 42R is reflected by the mirror 43R, passes through the lens 44R, and then enters the right eye 60R to be seen. Note that the image emitted from the display portion 32R also passes through the half mirror 46R, which does not contribute to seeing and is not illustrated here.

Similarly, an image emitted from the display portion 32L is reflected by the half mirror 46L and then enters the lens 42L. Next, the image emitted from the display portion 32L and then condensed by the lens 42L is reflected by the mirror 43L, passes through the lens 44L, and then enters the left eye 60L to be seen. Note that the image emitted from the display portion 32L also passes through the half mirror 46L, which does not contribute to seeing and is not illustrated here.

An image emitted from the display portion 34R passes through the half mirror 46R and then enters the lens 42R. Next, the image emitted from the display portion 34R and then condensed by the lens 42R is reflected by the mirror 43R, passes through the lens 44R, and then enters the right eye 60R to be seen. Note that the image emitted from the display portion 34R is also reflected by the half mirror 46R, which does not contribute to seeing and is not illustrated here.

Similarly, an image emitted from the display portion 34L passes through the half mirror 46L and then enters the lens 42L. Next, the image emitted from the display portion 34L and then condensed by the lens 42L is reflected by the mirror 43L, passes through the lens 44L, and then enters the left eye 60L to be seen. Note that the image emitted from the display portion 34L is also reflected by the half mirror 46L, which does not contribute to seeing and is not illustrated here.

FIG. 14B is a diagram schematically illustrating an image 70 that is synthesized to be seen. A high-definition image 71 that has been displayed on the display portion 34 with a high pixel density is positioned in a region corresponding to the central field of view. A low-definition image 72 that has been displayed on the display portion 32 with a low pixel density is positioned in a region corresponding to the peripheral field of view outside the central field of view. Since an edge portion is not clear in the human field of view, the outer periphery of the synthesized image is denoted by a dashed line here.

In order that the central field of view can always match the image 71, the electronic device preferably has a head tracking function of sensing the position of the user's head and changing an image. Since the head tracking function can minimize the movement of the eyeball, the user's line of sight can be easily gathered in the region of the image 71.

In the above manner, image information with high definition can be input to the central field of view (the fovea centralis and its vicinity of the human eye) and image information with low definition can be input to the peripheral field of view (the outside of the vicinity of the fovea centralis). Such an image can be seen with a reduced screen-door effect.

Although the description is made on the assumption that the pixel density of the display panel 33 is higher than the pixel density of the display panel 31, the present invention is not limited thereto. The pixel density of the display panel 33 may be lower than the pixel density of the display panel 31 or may be equal to the pixel density of the display panel 31.

In the display device 20B, one display panel may include the display portion 32R and the display portion 32L. In this case, the display device 20B includes a display panel including the display portion 32R and the display portion 32L, the display panel 33R including the display portion 34R, and the display panel 33L including the display portion 34L. With such a structure, the number of display panels can be reduced, resulting in a reduction in component costs and power consumption. In addition, frame synchronization, optical alignment, image quality adjustment, and the like of the left and right images can be easily performed.

FIG. 14A illustrates a structure in which an image emitted from the display portion 32 and an image emitted from the display portion 34 pass through the lens 42. Note that the present invention is not limited thereto. For example, a structure may be employed in which one of the image emitted from the display portion 32 and the image emitted from the display portion 34 passes through the lens 42.

Other structure examples of the display device of one embodiment of the present invention are described with reference to FIG. 15A to FIG. 15C. FIG. 15A is a plan view of the display device 20B. In FIG. 15A, part of an optical path is denoted by a dashed line.

The display device 20B illustrated in FIG. 15A is different from the display device 20 illustrated in FIG. 2A and FIG. 2B in including the half mirror 46 instead of the mirror 43 and in further including two display portions. The display device 20B illustrated in FIG. 15A is also a modification example of the display device 20B illustrated in FIG. 14A. Hereinafter, the contents already described with reference to FIG. 2A and FIG. 2B or the contents already described with reference to FIG. 14A are referred to for portions common to the contents, and the description of the portions is omitted.

Like the display device 20 described in <Structure example 1 of display device> above, the display device 20B illustrated in FIG. 15A includes the display unit 21R and the display unit 21L. The display unit 21R includes the display portion 32R, the mirror 41R, the lens 42R, and the lens 44R. The display unit 21L includes the display portion 32L, the mirror 41L, the lens 42L, and the lens 44L. The user can see the image when bringing the eyes near the lens 44R and the lens 44L that are included in the display device 20B.

The display unit 21R includes the half mirror 46R instead of the mirror 43R. Similarly, the display unit 21L includes the half mirror 46L instead of the mirror 43L.

The display unit 21R further includes the display panel 33R, and the display panel 33R includes the display portion 34R. The display portion 34R is placed so as to be positioned between the display portion 32R and the display portion 32L. Similarly, the display unit 21L further includes the display panel 33L, and the display panel 33L includes the display portion 34L. The display portion 34L is placed so as to be positioned between the display portion 32R and the display portion 32L.

That is, the display unit 21R includes two display panels. In addition, the display unit 21R includes two display portions. Similarly, the display unit 21L includes two display panels. In addition, the display unit 21L includes two display portions.

The display portion 34R and the lens 44R are positioned to face each other with the half mirror 46R therebetween. Similarly, the display portion 34L and the lens 44L are positioned to face each other with the half mirror 46L therebetween.

An image emitted from the display portion 32R is reflected by the mirror 41R and then enters the lens 42R. Next, the image emitted from the display portion 32R and then condensed by the lens 42R is reflected by the reflective surface of the half mirror 46R, passes through the lens 44R, and then enters the right eye 60R to be seen. Note that the image emitted from the display portion 32R also passes through the half mirror 46R, which does not contribute to seeing and is not illustrated here.

Similarly, an image emitted from the display portion 32L is reflected by the mirror 41L and then enters the lens 42L. Next, the image emitted from the display portion 32L and then condensed by the lens 42L is reflected by the reflective surface of the half mirror 46L, passes through the lens 44L, and then enters the left eye 60L to be seen. Note that the image emitted from the display portion 32L also passes through the half mirror 46L, which does not contribute to seeing and is not illustrated here.

An image emitted from the display portion 34R passes through the half mirror 46R and the lens 44R in this order and then enters the right eye 60R to be seen. Note that the image emitted from the display portion 34R is also reflected by the half mirror 46R, which does not contribute to seeing and is not illustrated here.

Similarly, an image emitted from the display portion 34L passes through the half mirror 46L and the lens 44L in this order and then enters the left eye 60L to be seen. Note that the image emitted from the display portion 34L is also reflected by the half mirror 46L, which does not contribute to seeing and is not illustrated here.

FIG. 15B is a right side view of the display device 20B. In FIG. 15B, part of the optical path is denoted by a dashed line.

The display device 20B illustrated in FIG. 15B is a modification example of the display device 20B illustrated in FIG. 15A. Specifically, the display device 20B illustrated in FIG. 15B is different from the display device 20B illustrated in FIG. 15A in the arrangement of the display panel 31R and the display panel 31L. Hereinafter, the contents already described with reference to FIG. 15A are referred to for portions common to the contents, and the description of the portions is omitted.

As illustrated in FIG. 15B, for example, the display panel 31R may be placed so that the front side of the center of the display portion 32R is positioned above the right eye 60R, and the display panel 31L may be placed so that the front side of the center of the display portion 32L is positioned above the left eye 60L. The description on the optical path in this case is similar to that in FIG. 15A and is omitted here.

FIG. 15C is a plan view of the display device 20B. In FIG. 15C, part of an optical path is denoted by a dashed line.

The display device 20B illustrated in FIG. 15C is different from the display device 20B illustrated in FIG. 15A in not including the mirror 41. Hereinafter, the contents already described with reference to FIG. 15A are referred to for portions common to the contents, and the description of the portions is omitted.

An image emitted from the display portion 32R passes through the lens 42R, is reflected by the reflective surface of the half mirror 46R, passes through the lens 44R, and then enters the right eye 60R to be seen. Note that the image emitted from the display portion 32R also passes through the half mirror 46R, which does not contribute to seeing and is not illustrated here.

Similarly, an image emitted from the display portion 32L passes through the lens 42L, is reflected by the reflective surface of the half mirror 46L, passes through the lens 44L, and then enters the left eye 60L to be seen. Note that the image emitted from the display portion 32L also passes through the half mirror 46L, which does not contribute to seeing and is not illustrated here.

Optical paths of the image emitted from the display portion 34R and the image emitted from the display portion 34L are similar to those in FIG. 15A and are omitted here.

With the structure illustrated in FIG. 15A, the structure illustrated in FIG. 15B, or the structure illustrated in FIG. 15C, a high-definition image that has been displayed on the display portion 34 with a high pixel density is positioned in a region corresponding to the central field of view, and a low-definition image that has been displayed on the display portion 32 with a low pixel density is positioned in a region corresponding to the peripheral field of view outside the central field of view. In the above manner, image information with high definition can be input to the central field of view (the fovea centralis and its vicinity of the human eye) and image information with low definition can be input to the peripheral field of view (the outside of the vicinity of the fovea centralis). Such an image can be seen with a reduced screen-door effect.

Furthermore, the image emitted from the display portion 32 passes through the lens 42 and the image emitted from the display portion 34 does not pass through the lens 42, so that the images at different magnifications can be synthesized.

Note that in the display device 20B illustrated in FIG. 15A, the display portion 34R and the display portion 34L are positioned between the display portion 32R and the display portion 32L and are close to each other. Thus, one display panel may include the display portion 34R and the display portion 34L. In this case, the display device 20B includes a display panel including the display portion 34R and the display portion 34L, the display panel 31R, and the display panel 31L. Alternatively, one display panel may include the display portion 32R, the display portion 34R, the display portion 34L, and the display portion 32L. In this case, the display device 20B includes a display panel including the display portion 32R, the display portion 34R, the display portion 34L, and the display portion 32L. Alternatively, one display panel may include the display portion 32R and the display portion 34R, and another display panel may include the display portion 34L and the display portion 32L. In this case, the display device 20B includes a first display panel including the display portion 32R and the display portion 34R and a second display panel including the display portion 34L and the display portion 32L.

In the display device 20B illustrated in FIG. 15B, the display portion 34R and the display portion 34L are close to each other and the display portion 32R and the display portion 32L and are close to each other. Thus, one display panel may include the display portion 34R and the display portion 34L. In this case, the display device 20B includes a display panel including the display portion 34R and the display portion 34L, the display panel 31R, and the display panel 31L. Alternatively, one display panel may include the display portion 32R and the display portion 32L. In this case, the display device 20B includes a display panel including the display portion 32R and the display portion 32L, the display panel 33R, and the display panel 33L. Alternatively, one display panel may include the display portion 34R and the display portion 34L, and another display panel may include the display portion 32R and the display portion 32L. In this case, the display device 20B includes a first display panel including the display portion 34R and the display portion 34L and a second display panel including the display portion 32R and the display portion 32L. Alternatively, one display panel may include the display portion 32R, the display portion 34R, the display portion 34L, and the display portion 32L. In this case, the display device 20B includes a display panel including the display portion 32R, the display portion 34R, the display portion 34L, and the display portion 32L. Alternatively, one display panel may include the display portion 32R and the display portion 34R, and another display panel may include the display portion 34L and the display portion 32L. In this case, the display device 20B includes a first display panel including the display portion 32R and the display portion 34R and a second display panel including the display portion 34L and the display portion 32L.

In the display device 20B illustrated in FIG. 15C, the display portion 34R and the display portion 34L are positioned between the display portion 32R and the display portion 32L and are close to each other. Thus, one display panel may include the display portion 34R and the display portion 34L. In this case, the display device 20B includes a display panel including the display portion 34R and the display portion 34L, the display panel 31R, and the display panel 31L.

With the above-described structure, the number of display panels can be reduced, resulting in a reduction in component costs and power consumption. In addition, frame synchronization, optical alignment, image quality adjustment, and the like of the left and right images can be easily performed.

### Structure Example 4 of Display Device

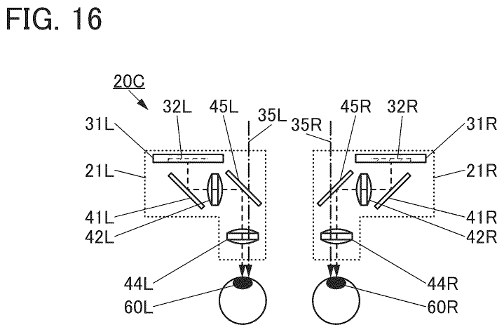

Another example of a structure of a display device that can be used for an electronic device of one embodiment of the present invention will be described with reference to FIG. 16.

FIG. 16 is a plan view of a display device 20C. Note that FIG. 16 can also be referred to as a cross-sectional view including an optical path and an optical axis. In FIG. 16, part of the optical path is denoted by a dashed line.

The display device 20C illustrated in FIG. 16 is different from the display device 20 illustrated in FIG. 2A and FIG. 2B in including a half mirror 45 instead of the mirror 43. Hereinafter, the contents already described with reference to FIG. 2A and FIG. 2B are referred to for portions common to the contents, and the description of the portions is omitted.

Like the display device 20 described in <Structure example 1 of display device> above, the display device 20C illustrated in FIG. 16 includes the display unit 21R and the display unit 21L. The display unit 21R includes the display portion 32R, the mirror 41R, the lens 42R, and the lens 44R. The display unit 21L includes the display portion 32L, the mirror 41L, the lens 42L, and the lens 44L. The user can see the image when bringing the eyes near the lens 44R and the lens 44L that are included in the display device 20C.

The display unit 21R includes a half mirror 45R instead of the mirror 43R. Similarly, the display unit 21L includes a half mirror 45L instead of the mirror 43L.

An image emitted from the display portion 32R is reflected by the mirror 41R and then enters the lens 42R. Next, the image emitted from the display portion 32R and then condensed by the lens 42R is reflected by a reflective surface of the half mirror 45R, passes through the lens 44R, and then enters the right eye 60R to be seen. Note that the image emitted from the display portion 32R also passes through the half mirror 45R, which does not contribute to seeing and is not illustrated here.

Similarly, an image emitted from the display portion 32L is reflected by the mirror 41L and then enters the lens 42L. Next, the image emitted from the display portion 32L and then condensed by the lens 42L is reflected by a reflective surface of the half mirror 45L, passes through the lens 44L, and then enters the left eye 60L to be seen. Note that the image emitted from the display portion 32L also passes through the half mirror 45L, which does not contribute to seeing and is not illustrated here.

External light 35R entering from the outside of the display device 20C passes through the half mirror 45R and the lens 44R in this order and then enters the right eye 60R to be seen. Similarly, external light 35L entering from the outside of the display device 20C passes through the half mirror 45L and the lens 44L in this order and then enters the left eye 60L to be seen. In FIG. 16, part of the external light is denoted by a dashed line.

Note that a structure may be employed in which the external light 35R entering from the outside of the display device 20C does not pass through the lens 44R. In this case, the external light 35R passes through the half mirror 45R and enters the right eye 60R to be seen. Similarly, a structure may be employed in which the external light 35L entering from the outside of the display device 20C does not pass through the lens 44L. In this case, the external light 35L passes through the half mirror 45L and enters the left eye 60L to be seen.

The above-described structure enables the user to see the image emitted from the display portion 32R and the external light 35R with the right eye and see the image emitted from the display portion 32L and the external light 35L with the left eye. The user can see the image emitted from the display portion 32 and the scenery which are superimposed on each other. Thus, an electronic device including the display device 20C is capable of AR display.

### Structure Example of Electronic Device

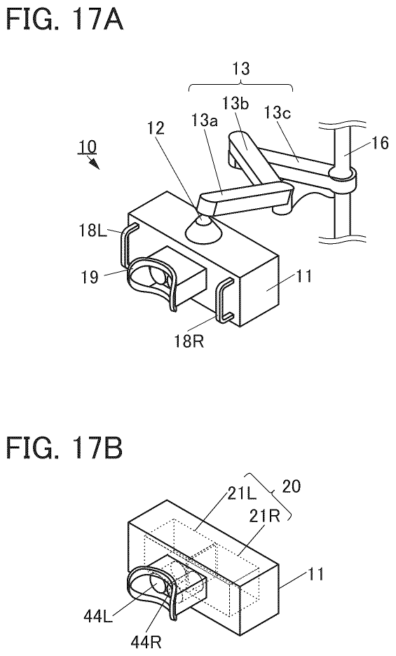

A structure example of an electronic device of one embodiment of the present invention will be described with reference to FIG. 17A and FIG. 17B.

FIG. 17A and FIG. 17B are diagrams showing an example of an electronic device 10 including the display device 20. In FIG. 17B, the display unit 21R and the display unit 21L that are included in the display device 20 are denoted by dashed lines. Note that the electronic device 10 preferably includes any one of the display device 20, the display device 20A, the display device 20B, and the display device 20C that are described above.

The electronic device 10 includes a housing 11, an articulated arm 13, a handle 18R, a handle 18L, a cushion 19, and the like. The display device 20 is incorporated in the housing 11. The housing 11 is connected to a support rod 16 through the articulated arm 13.

The display unit 21R and the display unit 21L each include a housing, and components of the display unit (a lens, a mirror, and the like) are provided inside the housing. The dashed line shown in FIG. 17B also denotes an example of the outline of the housing. The housing preferably has a mechanism for adjusting the positions or angles of the components. This enables focus adjustment, zooming in/out of an image, or the like.

The display unit 21R and the display unit 21L are incorporated in the housing 11 so that surfaces of the lens 44R and the lens 44L are exposed on the inner side (user's side). The display unit 21R is for a right eye, the display unit 21L is for a left eye, and each of the display units displays an image using parallax, so that the image can be perceived as a three-dimensional image.

A guide rail may be provided inside the housing 11. In that case, the display unit 21R and the display unit 21L preferably slide along the guide rail. Such a structure enables adjustment of the distance between the lens 44R and the lens 44L. Thus, the lens 44R and the lens 44L can be placed at the most appropriate positions in accordance with the positions of the user's eyes.

The electronic device 10 preferably has a function of measuring a pupillary distance. On the basis of the user's pupillary distance measured by this function, the arrangement of the display unit 21R and the display unit 21L (in particular, the arrangement of the lens 44R and the lens 44L) can be automatically determined.

The housing 11 may be provided with an input terminal and an output terminal. To the input terminal, a cable for supplying a video signal from a video output device or the like, power for charging a battery provided in the housing 11, or the like can be connected. The output terminal can function as, for example, an audio output terminal to which earphones, headphones, or the like can be connected. Note that in the case where audio data can be output by wireless communication or sound is output from an external video output device, the audio output terminal is not necessarily provided.

In addition, a wireless communication module, a memory module, and the like may be provided inside the housing 11. Contents to be watched can be downloaded via wireless communication using the wireless communication module and can be stored in the memory module. Accordingly, the user can watch the downloaded contents offline whenever the user wants.

A sight line sensor may be provided inside the housing 11. For example, operation buttons for power-on, power-off, sleep, volume control, channel change, menu display, selection, decision, and back, and operation buttons for play, stop, pause, fast forward, and fast backward of moving images are displayed and visually recognized, so that the respective operations can be performed.

A motion detection portion may be provided inside the housing 11. The motion detection portion includes an inertial sensor having a function of sensing the motion of the user's head. Note that the inertial sensor here refers to a sensor for sensing the acceleration and angular velocity of an object.

The articulated arm 13 includes an arm 13a, an arm 13b, and an arm 13c. The arm 13a is fastened to an upper portion of the housing 11. In other words, the upper portion of the housing 11 is fixed to the arm 13a. The arm 13a is connected to the housing 11 so as to be revolvable centering around a point 12. Bendable or revolvable axes are provided between the arm 13a and the arm 13b and between the arm 13b and the arm 13c. Accordingly, the articulated arm 13 can follow and support the housing 11 moved in various directions. With such a structure, the weight of the housing 11 felt by the user can be reduced as much as possible.

In FIG. 17A, the articulated arm 13 is composed of three arms (the arm 13a to the arm 13c). Note that the present invention is not limited thereto. The articulated arm 13 may be composed of two or four or more arms. The articulated arm 13 may be an articulated arm provided with an axis that limits the direction of movement to only one direction (a vertical direction or a horizontal direction) or only two directions (a vertical direction and a horizontal direction). The articulated arm 13 may include a spring, an extendable arm, or the like.

The support rod 16 may be fixed to a ceiling, a wall, or a floor. Alternatively, the support rod 16 may be attached to a carriable housing. The articulated arm 13 may be fixed to a ceiling, a wall, or a floor without providing the support rod 16.

When the handle 18R and the handle 18L are provided on the outer side of the housing 11, the user can easily attach and detach the housing 11.

The cushion 19 is a portion in contact with the user's face (forehead, cheek, or the like). The cushion 19 is in close contact with the user's face, so that light leakage can be prevented, which further increases the sense of immersion. A soft material is preferably used for the cushion 19 so that the cushion 19 is in close contact with the face of the user wearing the electronic device 10. For example, a material such as rubber, silicone rubber, urethane, or sponge can be used. Furthermore, when a sponge or the like whose surface is covered with cloth, leather (natural leather or synthetic leather), or the like is used, a gap is less likely to be generated between the user's face and the cushion 19, so that light leakage can be suitably prevented. Using such a material is preferable because it has a soft texture and the user does not feel cold when wearing the electronic device 10 in a cold season, for example. The member in contact with user's skin, such as the cushion 19, is preferably detachable because cleaning or replacement can be easily performed.

By using the display device 20 of one embodiment of the present invention for the electronic device 10, an electronic device enabling a wide field of view can be provided. Alternatively, an electronic device capable of displaying a three-dimensional image by a parallax method can be provided. Alternatively, an electronic device that provides a high-quality image to be seen can be provided. Alternatively, an electronic device that can be easily attached and detached can be provided.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

At least part of the structure examples, the drawings corresponding thereto, and the like described as an example in this embodiment can be combined with the other structure examples, the other drawings corresponding thereto, and the like as appropriate.

### Embodiment 2

In this embodiment, structure examples of a display panel that can be used for the electronic device of one embodiment of the present invention will be described. A display panel described below as an example can be used as the display panel 31 in Embodiment 1.

One embodiment of the present invention is a display panel including light-emitting elements (also referred to as light-emitting devices). The display panel includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers containing different light-emitting materials. For example, when three kinds of light-emitting elements that emit red (R), green (G), and blue (B) light are included, a full-color display panel can be achieved.

In the case of manufacturing a display panel including a plurality of light-emitting elements of different emission colors, at least layers (light-emitting layers) containing light-emitting materials each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high definition and a high aperture ratio of the display panel. In addition, the outline of the layer might blur during evaporation, so that the thickness of an end portion might be reduced. That is, the thickness of an island-shaped light-emitting layer might vary from place to place. In addition, in the case of manufacturing a display panel with a large size, a high resolution, or a high definition, a manufacturing yield might be reduced because of low dimensional accuracy of the metal mask and deformation due to heat or the like. Thus, a measure has been taken for a pseudo increase in definition (also referred to as pixel density) by employing unique pixel arrangement such as PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by a photolithography method without using a shadow mask such as a fine metal mask (FMM). Accordingly, it is possible to achieve a display panel with a high definition and a high aperture ratio, which has been difficult to achieve. Moreover, since the EL layers can be formed separately, it is possible to achieve a display panel that performs extremely clear display with high contrast and high display quality. Note that, fine patterning of the EL layers may be performed using both a metal mask and a photolithography method, for example.

In addition, part or the whole of the EL layer can be physically divided from each other. This can inhibit leakage current flowing between adjacent light-emitting elements through a layer (also referred to as a common layer) shared by the light-emitting elements. Thus, it is possible to prevent crosstalk due to unintended light emission, so that a display panel with extremely high contrast can be achieved. In particular, a display panel having high current efficiency at low luminance can be achieved.

In one embodiment of the present invention, the display panel can also be obtained by combining a light-emitting element that emits white light with a color filter. In that case, light-emitting elements having the same structure can be used as light-emitting elements provided in pixels (subpixels) that emit light of different colors, which allows all the layers to be common layers. In addition, part or the whole of the EL layer may be divided from each other in a step using a photolithography method. Thus, leakage current through the common layer is inhibited; accordingly, a high-contrast display panel can be achieved. In particular, when an element has a tandem structure in which a plurality of light-emitting layers are stacked with a highly conductive intermediate layer therebetween, leakage current through the intermediate layer can be effectively prevented, so that a display panel with high luminance, high definition, and high contrast can be achieved.

In the case where the EL layer is processed by a photolithography method, part of the light-emitting layer is sometimes exposed to cause degradation. Thus, an insulating layer covering at least the side surface of the island-shaped light-emitting layer is preferably provided. The insulating layer may cover part of the top surface of an island-shaped EL layer. For the insulating layer, a material having a barrier property against water and oxygen is preferably used. For example, an inorganic insulating film that does not easily allow diffusion of water or oxygen can be used. This can inhibit deterioration of the EL layer and can achieve a highly reliable display panel.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a local step positioned between the two adjacent light-emitting elements is preferably filled with a resin layer functioning as a planarization film (also referred to as LFP: Local Filling Planarization). The resin layer has a function of a planarization film. This structure can inhibit disconnection of the common layer or the common electrode and can achieve a highly reliable display panel.

More specific structure examples of the display panel of one embodiment of the present invention will be described below with reference to drawings.

### Structure Example 1

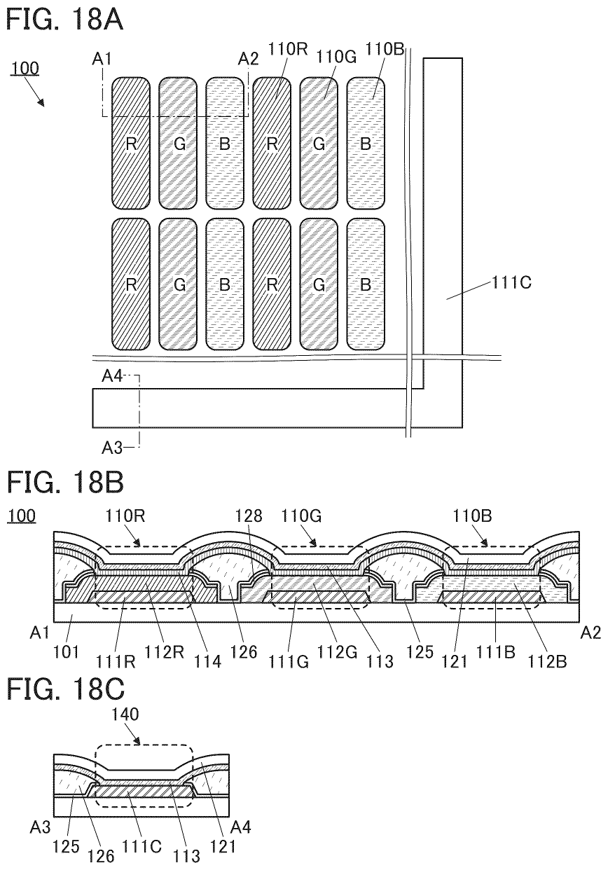

FIG. 18A is a schematic top view of a display panel 100 of one embodiment of the present invention. The display panel 100 includes, over a substrate 101, a plurality of light-emitting elements 110R exhibiting red, a plurality of light-emitting elements 110G exhibiting green, and a plurality of light-emitting elements 110B exhibiting blue. In FIG. 18A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 18A illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As the light-emitting substance contained in the EL element, not only an organic compound but also an inorganic compound (a quantum dot material or the like) can be used.

FIG. 18A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided along two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like. Note that in this specification and the like, a top surface shape refers to a shape in a plan view, i.e., a shape seen from above.

FIG. 18B and FIG. 18C are schematic cross-sectional views corresponding to the dashed-dotted line A1-A2 and the dashed-dotted line A3-A4 in FIG. 18A. FIG. 18B is a schematic cross-sectional view of the light-emitting element 110R, the light-emitting element 110G, and the light-emitting element 110B, and FIG. 18C is a schematic cross-sectional view of a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting substance (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

Each of the organic layer 112 and the common layer 114 can independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a light-transmitting property with respect to visible light is used for either the pixel electrodes or the common electrode 113, and a conductive film having a reflective property is used for the other. When the pixel electrodes have light-transmitting properties and the common electrode 113 has a reflective property, a bottom-emission display panel can be obtained. In contrast, when the pixel electrodes have reflective properties and the common electrode 113 has a light-transmitting property, a top-emission display panel can be obtained. Note that when both the pixel electrodes and the common electrode 113 have light-transmitting properties, a dual-emission display panel can be obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a material (for example, also referred to as dust or particles) in a manufacturing step is easily removed by processing such as cleaning, which is preferable.

Note that in this specification and the like, a tapered shape indicates a shape in which at least part of the side surface of a structure is inclined to a substrate surface. For example, a tapered shape preferably includes a region where an angle formed between the inclined side surface and the substrate surface (such an angle is also referred to as a taper angle) is less than 90°.

The organic layer 112 is processed into an island shape by a photolithography method. Thus, an angle formed between the top surface and the side surface of an end portion of the organic layer 112 is approximately 90°. In contrast, an organic film formed using an FMM (Fine Metal Mask) or the like has a thickness that tends to gradually decrease with decreasing distance from an end portion, and has a top surface forming a slope in an area extending in the range of greater than or equal to 1 μm and less than or equal to 10 μm, for example; thus, such an organic film has a shape whose top surface and side surface are difficult to distinguish from each other.

An insulating layer 125, a resin layer 126, and a layer 128 are included between two adjacent light-emitting elements.

Between two adjacent light-emitting elements, the side surfaces of the organic layers 112 are provided to face each other with the resin layer 126 therebetween. The resin layer 126 is positioned between the two adjacent light-emitting elements and is provided to fill regions between end portions of the organic layers 112 and between the two organic layers 112. The resin layer 126 has a top surface with a smooth convex shape, and the common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon where the common electrode 113 is divided by a step at an end portion of the organic layer 112 (such a phenomenon is also referred to as disconnection) from occurring and the common electrode over the organic layer 112 from being insulated.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layer 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved in an organic solvent or the like used at the time of forming the resin layer 126. Therefore, the insulating layer 125 is provided between the organic layer 112 and the resin layer 126 to protect the side surface of the organic layer 112.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method that provides good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for each of the insulating layer 125 and the layer 128.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is interposed between a pair of inorganic insulating films is preferable. Furthermore, the organic insulating film preferably functions as a planarization film. This enables the top surface of the organic insulating film to be flat, which results in improved coverage with the inorganic insulating film thereover and a higher barrier property. Moreover, the top surface of the protective layer 121 is flat, which is preferable because the influence of an uneven shape due to a lower structure can be reduced in the case where a component (e.g., a color filter, an electrode of a touch sensor, a lens array, or the like) is provided above the protective layer 121.

FIG. 18C illustrates the connection portion 140 where the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 18C illustrates the connection portion 140 where the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin; thus, problems do not arise in many cases even when the common layer 114 is positioned in the connection portion 140. Accordingly, the common electrode 113 and the common layer 114 can be formed using the same shielding mask, so that manufacturing costs can be reduced.

### Structure Example 2

A display panel whose structure is partly different from that of Structure example 1 is described below. Note that the above description is referred to for portions common to those in Structure example 1, and the description is omitted in some cases.

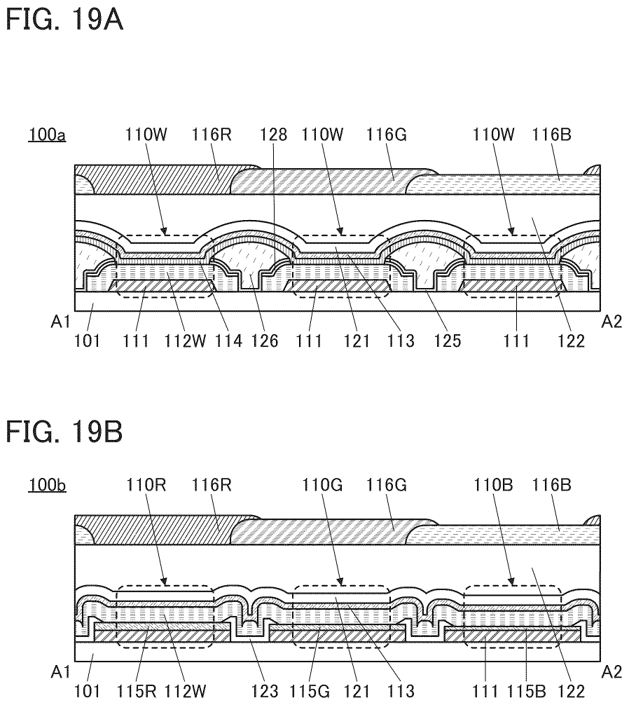

FIG. 19A is a schematic cross-sectional view of a display panel 100a. The display panel 100a is different from the display panel 100 mainly in the structure of the light-emitting element and including a coloring layer.

The display panel 100a includes light-emitting elements 110W that emit white light. The light-emitting elements 110W each include the pixel electrode 111, an organic layer 112W, the common layer 114, and the common electrode 113. The organic layer 112W emits white light. For example, the organic layer 112W can contain two or more kinds of light-emitting materials whose emission colors are complementary colors. For example, the organic layer 112W can contain a light-emitting organic compound that emits red light, a light-emitting organic compound that emits green light, and a light-emitting organic compound that emits blue light. Alternatively, the organic layer 112W may contain a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display panel can achieve high contrast and high color reproducibility.

An insulating layer 122 that functions as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 is a formation surface on which the coloring layer 116R, the coloring layer 116G, and the coloring layer 116B are formed; thus, with the flat top surface of the insulating layer 122, the thickness of the coloring layer 116R or the like can be uniform and color purity can be increased. Note that when the thickness of the coloring layer 116R or the like is non-uniform, the amount of light absorption varies from area to area in the coloring layer 116R, which might decrease the color purity.

### Structure Example 3

FIG. 19B is a schematic cross-sectional view of a display panel 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film reflecting visible light is used for the pixel electrode 111 and a film having a property of reflecting and transmitting visible light is used for the common electrode 113, so that a micro resonator (microcavity) structure can be achieved. In that case, by adjusting the thicknesses of the conductive layer 115R, the conductive layer 115G, and the conductive layer 115B to obtain optimal optical path length, light with different wavelengths and increased intensities can be obtained from the light-emitting element 110R, the light-emitting element 110G, and the light-emitting element 110B even when the organic layer 112 that emits white light is used.

Furthermore, the coloring layer 116R, the coloring layer 116G, and the coloring layer 116B are provided on the optical paths of the light-emitting element 110R, the light-emitting element 110G, and the light-emitting element 110B, respectively, so that light with high color purity can be obtained.

In addition, an insulating layer 123 that covers the end portion of the pixel electrode 111 and end portions of the conductive layer 115R, the conductive layer 115G, and the conductive layer 115B is provided. An end portion of the insulating layer 123 preferably has a tapered shape. When the insulating layer 123 is provided, coverage with the organic layer 112W, the common electrode 113, the protective layer 121, and the like provided over the insulating layer 123 can be increased.

The organic layer 112W and the common electrode 113 are each provided as one continuous film shared by the light-emitting elements. Such a structure is preferable because the manufacturing process of the display panel can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Accordingly, leakage current generated between adjacent light-emitting elements through the organic layer 112W can be inhibited without processing the organic layer 112W by a photolithography method or the like.

The above is the description of the structure example of the display panel.

### Pixel Layout

Pixel layout different from that in FIG. 18A will be mainly described below. There is no particular limitation on the arrangement of light-emitting elements (subpixels), and a variety of methods can be employed.

In addition, examples of a top surface shape of the subpixel include polygons such as a triangle, a quadrangle (including a rectangle and a square), and a pentagon; these polygons with rounded corners; an ellipse; and a circle. Here, the top surface shape of the subpixel corresponds to a top surface shape of a light-emitting region of the light-emitting element.

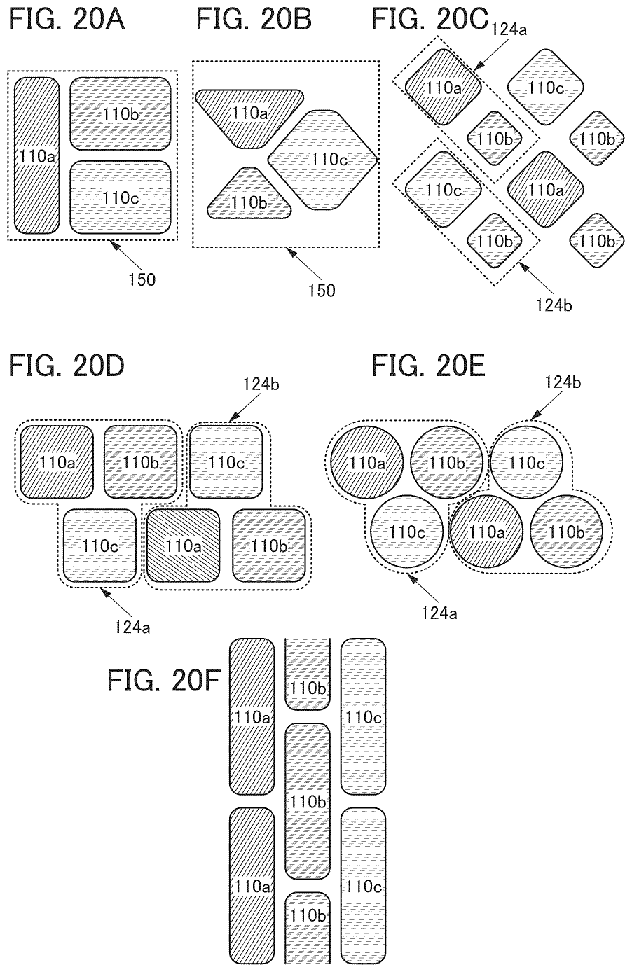

A pixel 150 illustrated in FIG. 20A employs S-stripe arrangement. The pixel 150 illustrated in FIG. 20A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 20B includes the light-emitting element 110a whose top surface has a rough trapezoidal or rough triangle shape with rounded corners, the light-emitting element 110b whose top surface has a rough trapezoidal or rough triangle shape with rounded corners, and the light-emitting element 110c whose top surface has a rough quadrangular or rough hexagonal shape with rounded corners. In addition, the light-emitting element 110a has a larger light-emitting area than the light-emitting element 110b. In this manner, the shapes and sizes of the light-emitting elements can be independently determined. For example, the size of a light-emitting element with higher reliability can be made smaller. For example, the light-emitting element 110a may be a green-light-emitting element, the light-emitting element 110b may be a red-light-emitting element, and the light-emitting element 110c may be a blue-light-emitting element.

Pixels 124a and 124b illustrated in FIG. 20C employ PenTile arrangement. FIG. 20C shows an example in which the pixels 124a each including the light-emitting element 110a and the light-emitting element 110b and the pixels 124b each including the light-emitting element 110b and the light-emitting element 110c are alternately arranged. For example, the light-emitting element 110a may be a red-light-emitting element, the light-emitting element 110b may be a green-light-emitting element, and the light-emitting element 110c may be a blue-light-emitting element.

The pixels 124a and 124b illustrated in FIG. 20D and FIG. 20E employ delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red-light-emitting element, the light-emitting element 110b may be a green-light-emitting element, and the light-emitting element 110c may be a blue-light-emitting element.

FIG. 20D shows an example in which the top surface of each light-emitting element has a rough quadrangular shape with rounded corners, and FIG. 20E shows an example in which the top surface of each light-emitting element is circular.

FIG. 20F shows an example in which light-emitting elements of different colors are arranged in a zigzag manner. Specifically, the positions of top sides of two light-emitting elements arranged in a row direction (e.g., the light-emitting element 110a and the light-emitting element 110b or the light-emitting element 110b and the light-emitting element 110c) are not aligned in a top view. For example, the light-emitting element 110a may be a red-light-emitting element, the light-emitting element 110b may be a green-light-emitting element, and the light-emitting element 110c may be a blue-light-emitting element.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel of one embodiment of the present invention, the EL layer is processed into an island shape with use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, the top surface of the EL layer has a poly gonal shape with rounded corners, an elliptical shape, a circular shape, or the like in some cases. For example, when a resist mask with a square top surface is intended to be formed, a resist mask with a circular top surface might be formed, and the top surface of the EL layer might be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

At least part of the structure examples, the drawings corresponding thereto, and the like described as an example in this embodiment can be combined with the other structure examples, the other drawings corresponding thereto, and the like as appropriate.

### Embodiment 3

In this embodiment, other structure examples of a display panel that can be used for the electronic device of one embodiment of the present invention will be described.

Display panels in this embodiment are high-definition display panels, and particularly suitably used for display portions of wearable devices that can be worn on a head, such as VR devices like HMDs and glasses-type AR devices.

### Display Module

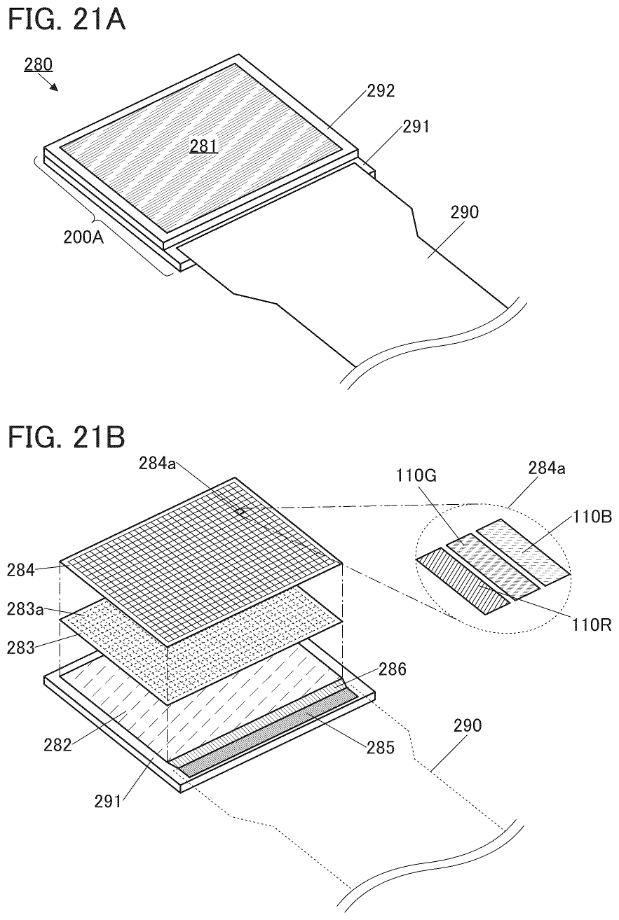

FIG. 21A is a perspective view of a display module 280. The display module 280 includes a display panel 200A and an FPC 290. Note that a display panel included in the display module 280 is not limited to the display panel 200A and may be any of a display panel 200B to a display panel 200F described later.

The display module 280 includes a substrate 291 and a substrate 292. The display module 280 includes a display portion 281. The display portion 281 is a region where an image is displayed.

FIG. 21B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. In addition, a terminal portion 285 to be connected to the FPC 290 is provided in a portion that is over the substrate 291 and does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 21B. The pixel 284a includes the light-emitting element 110R that emits red light, the light-emitting element 110G that emits green light, and the light-emitting element 110B that emits blue light.

The pixel circuit portion 283 includes a plurality of pixel circuits 283a arranged periodically. One pixel circuit 283a is a circuit for controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may further include at least one of an arithmetic circuit, a memory circuit, a power supply circuit, and the like. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. In addition, an IC may be mounted on the FPC 290.

The display module 280 can have a structure in which one or both of the pixel circuit portion 283 and the circuit portion 282 are provided to be stacked below the pixel portion 284; thus, the aperture ratio (effective display area ratio) of the display portion 281 can be significantly high. For example, the aperture ratio of the display portion 281 can be greater than or equal to 40 % and less than 100 %, preferably greater than or equal to 50 % and less than or equal to 95 %, further preferably greater than or equal to 60 % and less than or equal to 95 %. Furthermore, the pixels 284a can be arranged extremely densely and thus the display portion 281 can have an extremely high definition. For example, the pixels 284a are preferably arranged in the display portion 281 with a definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high definition, and thus can be suitably used for a VR device such as an HMD or a glasses-type AR device. For example, even in the case of a structure in which the display portion of the display module 280 is seen through a lens, pixels of the extremely-high-definition display portion 281 included in the display module 280 are not seen even when the display portion is enlarged by the lens, so that display providing a high sense of immersion can be performed. Without being limited thereto, the display module 280 can also be suitably used for an electronic device having a relatively small display portion. For example, the display module 280 can be suitably used for a display portion of a wearable electronic device such as a wristwatch.

### Display Panel 200A

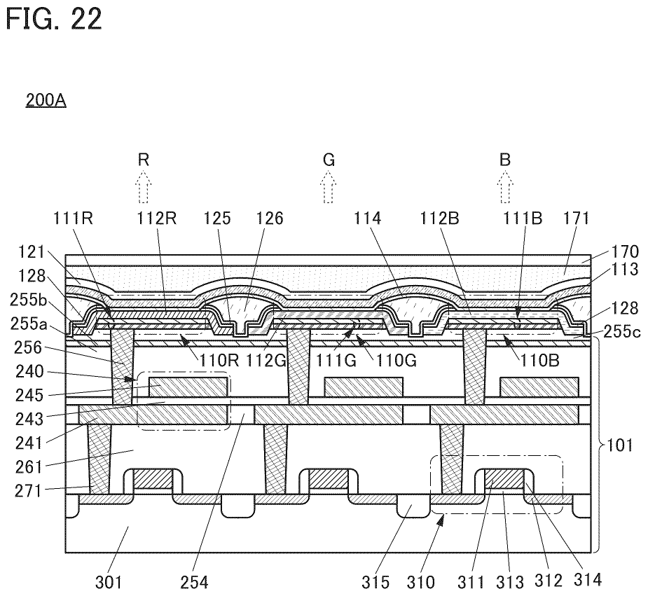

The display panel 200A illustrated in FIG. 22 includes a substrate 301, the light-emitting elements 110R, 110G, and 110B, a capacitor 240, and a transistor 310.

The substrate 301 corresponds to the substrate 291 in FIG. 21A and FIG. 21B.

The transistor 310 is a transistor whose channel formation region is formed in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

In addition, an element isolation layer 315 is provided between two adjacent transistors 310 to be embedded in the substrate 301.

Furthermore, an insulating layer 261 is provided to cover the transistors 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment shows an example in which the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c. Embodiment 2 can be referred to for the structures of the light-emitting element 110R, the light-emitting element 110G, and the light-emitting element 110B.

Since the light-emitting devices for different emission colors are separately formed in the display panel 200A, the difference between the chromaticity at low luminance emission and that at high luminance emission is small. Furthermore, since the organic layers 112R, 112G, and 112B are apart from each other, crosstalk generated between adjacent subpixels can be inhibited even when the display panel has a high definition. It is thus possible to achieve a display panel that has a high definition and high display quality.

In a region between adjacent light-emitting elements, the insulating layer 125, the resin layer 126, and the layer 128 are provided.

The pixel electrode 111R, the pixel electrode 111G, and the pixel electrode 111B of the light-emitting elements are each electrically connected to one of the source and the drain of the transistor 310 through a plug 256 that is embedded in the insulating layer 255a, the insulating layer 255b, and the insulating layer 255c, the conductive layer 241 that is embedded in the insulating layer 254, and the plug 271 that is embedded in the insulating layer 261. The top surface of the insulating layer 255c and the top surface of the plug 256 are level with or substantially level with each other. A variety of conductive materials can be used for the plugs.

In addition, the protective layer 121 is provided over the light-emitting elements 110R, 110G, and 110B. A substrate 170 is attached onto the protective layer 121 with an adhesive layer 171.

An insulating layer covering an end portion of the top surface of the pixel electrode 111 is not provided between two adjacent pixel electrodes 111. Thus, the distance between adjacent light-emitting elements can be extremely shortened. Accordingly, the display panel can have a high definition or a high resolution.

### Display Panel 200B

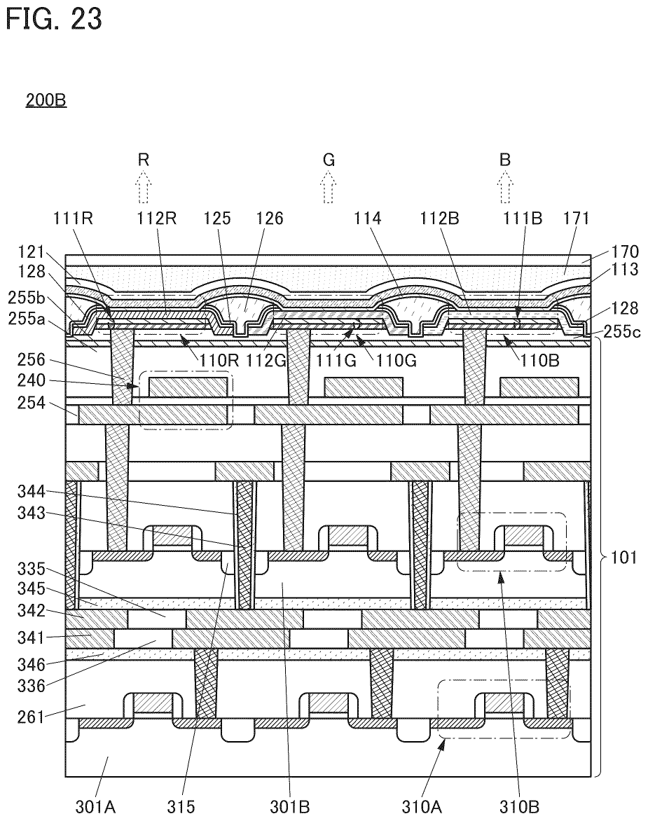

The display panel 200B illustrated in FIG. 23 has a structure in which a transistor 310A and a transistor 310B in each of which a channel is formed in a semiconductor substrate are stacked. Note that in the following description of the display panel, the description of portions similar to those of the above-described display panel is omitted in some cases.

The display panel 200B has a structure in which a substrate 301B provided with the transistor 310B, the capacitor 240, and the light-emitting devices is attached to a substrate 301A provided with the transistors 310A.

Here, an insulating layer 345 is provided on the bottom surface of the substrate 301B, and an insulating layer 346 is provided over the insulating layer 261 provided over the substrate 301A. The insulating layers 345 and 346 are insulating layers functioning as protective layers and can inhibit diffusion of impurities into the substrate 301B and the substrate 301A. For each of the insulating layers 345 and 346, an inorganic insulating film that can be used for the protective layer 121 can be used.

The substrate 301B is provided with a plug 343 that penetrates the substrate 301B and the insulating layer 345. Here, an insulating layer 344 functioning as a protective layer is preferably provided to cover the side surface of the plug 343.

In addition, a conductive layer 342 is provided under the insulating layer 345 on the substrate 301B. The conductive layer 342 is embedded in an insulating layer 335, and the bottom surfaces of the conductive layer 342 and the insulating layer 335 are planarized. Furthermore, the conductive layer 342 is electrically connected to the plug 343.

In contrast, a conductive layer 341 is provided over the insulating layer 346 over the substrate 301A. The conductive layer 341 is embedded in an insulating layer 336, and the top surfaces of the conductive layer 341 and the insulating layer 336 are planarized.

The same conductive material is preferably used for the conductive layer 341 and the conductive layer 342. A metal film containing an element selected from Al, Cr, Cu, Ta, Ti, Mo, and W, a metal nitride film containing the above element as a component (a titanium nitride film, a molybdenum nitride film, or a tungsten nitride film), or the like can be used, for example. Copper is particularly preferably used for the conductive layer 341 and the conductive layer 342. Accordingly, it is possible to employ a Cu-to-Cu (copper-to-copper) direct bonding technique (a technique for achieving electrical continuity by connecting Cu (copper) pads to each other).

### Display Panel 200C

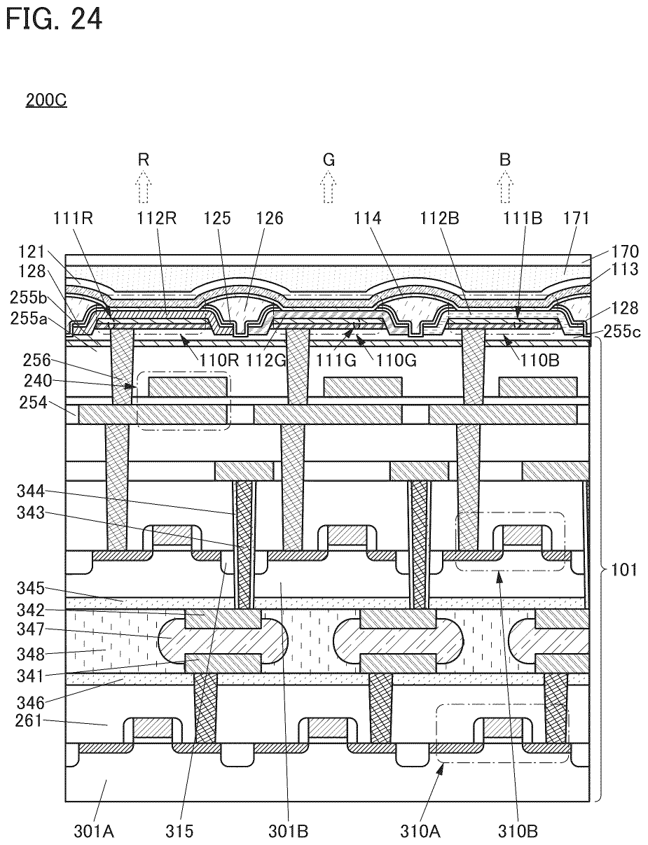

The display panel 200C illustrated in FIG. 24 has a structure in which the conductive layer 341 and the conductive layer 342 are bonded to each other through a bump 347.

As illustrated in FIG. 24, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder is used for the bump 347 in some cases. In addition, an adhesive layer 348 may be provided between the insulating layer 345 and the insulating layer 346. Furthermore, in the case where the bump 347 is provided, a structure without the insulating layer 335 and the insulating layer 336 may be employed.

### Display Panel 200D and Display Panel 200E

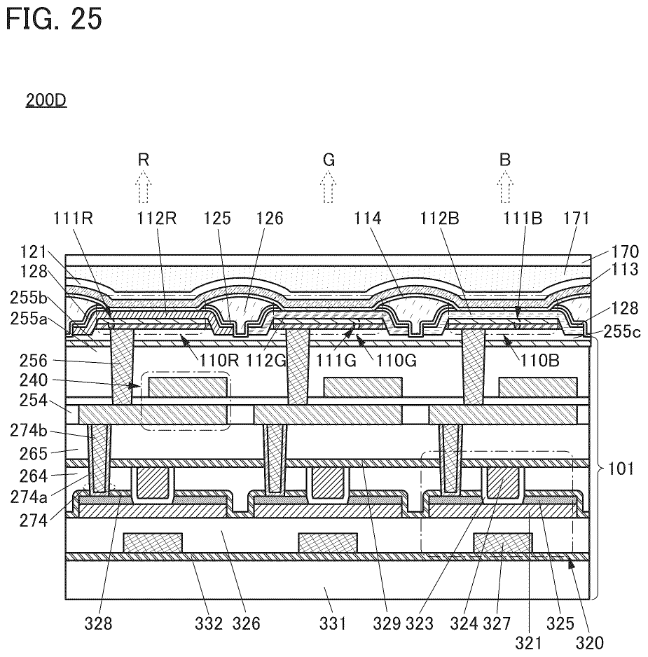

The display panel 200D illustrated in FIG. 25 differs from the display panel 200A mainly in a transistor structure.

A transistor 320 is a transistor (an OS transistor) in which a metal oxide (also referred to as an oxide semiconductor) is used for a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 21A and FIG. 21B. As the substrate 331, an insulating substrate such as a glass substrate, a flexible substrate, a laminate film, a base film, or the like can be used. In particular, the substrate 331 with flexibility enables a bendable display panel.

As materials of the flexible substrate, the laminate film, the base film, or the like, polyethylene terephthalate (PET), polyethylene naphthalate (PEN), polyether sulfone (PES), polytetrafluoroethylene (PTFE), polypropylene, polyester, polyvinyl fluoride, polyvinyl chloride, polyolefin, polyamide (e.g., nylon or aramid), polyimide, polycarbonate, aramid, an epoxy resin, or an acrylic resin can be used, for example.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film that is less likely to allow diffusion of hydrogen or oxygen than a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided over and in contact with the semiconductor layer 321, and functions as a source electrode and a drain electrode.

An insulating layer 328 is provided to cover the top surface and the side surface of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. For the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with the top surface of the semiconductor layer 321 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment so that they are level with or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surfaces of openings in the insulating layer 265, the insulating layer 329, the insulating layer 264, and the insulating layer 328 and part of the top surface of the conductive layer 325, and a conductive layer 274b in contact with the top surface of the conductive layer 274a. In that case, a conductive material that does not easily allow diffusion of hydrogen and oxygen is preferably used for the conductive layer 274a.

Note that there is no particular limitation on the structures of the transistors included in the display panel of this embodiment. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer where a channel is formed.

A structure in which the semiconductor layer where a channel is formed is interposed between two gates is employed for the transistor 320. The two gates may be connected to each other and supplied with the same signal to drive the transistor. Alternatively, a potential for controlling the threshold voltage may be supplied to one of the two gates and a potential for driving may be supplied to the other of the two gates to control the threshold voltage of the transistor.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

The bandgap of a metal oxide used for the semiconductor layer of the transistor is preferably greater than or equal to 2 eV, further preferably greater than or equal to 2.5 eV. The use of a metal oxide having a wide bandgap can reduce the off-state current of the OS transistor.

A metal oxide preferably contains at least indium or zinc, and further preferably contains indium and zinc. A metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (low-temperature polysilicon, single crystal silicon, or the like).

Examples of the metal oxide that can be used for the semiconductor layer include indium oxide, gallium oxide, and zinc oxide. In addition, the metal oxide preferably contains two or three kinds selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

It is particularly preferable that an oxide containing indium, gallium, and zinc (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium, aluminum, and zinc (also referred to as IAZO). Alternatively, it is preferable to use an oxide containing indium, aluminum, gallium, and zinc (also referred to as IAGZO).

In the case where the metal oxide used for the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30 % of a desired atomic ratio. In the case where the metal oxide used for the semiconductor layer is an In—Zn oxide, examples of the atomic ratio of the metal elements in the In—Zn oxide include In:Zn=1:1 or a composition in the neighborhood thereof, In:Zn=2:1 or a composition in the neighborhood thereof, and In:Zn=4:1 or a composition in the neighborhood thereof.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, when the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, when the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

Alternatively, the semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M.

Alternatively, a stacked-layer structure or the like of one selected from indium oxide, indium gallium oxide, and IGZO, and one selected from IAZO, IAGZO, and ITZO (registered trademark) may be used, for example.

Examples of an oxide semiconductor having crystallinity include a CAAC (c-axis aligned crystalline)-OS and an nc (nanocrystalline)-OS.

An OS transistor has extremely higher field-effect mobility than a transistor using amorphous silicon. In addition, the OS transistor has extremely low leakage current between a source and a drain in an off state (also referred to as off-state current), and charge accumulated in a capacitor that is connected in series with the transistor can be retained for a long period. Furthermore, the power consumption of the display panel can be reduced with use of the OS transistor.

In addition, to increase the emission luminance of the light-emitting device included in the pixel circuit, the amount of current flowing through the light-emitting device needs to be increased. To increase the current amount, the source-drain voltage of a driving transistor included in the pixel circuit needs to be increased. Since the OS transistor has higher breakdown voltage between the source and the drain than a Si transistor (a transistor containing silicon in a semiconductor layer where a channel is formed), high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

In addition, when transistors operate in a saturation region, a change in source-drain current relative to a change in gate-source voltage is smaller in an OS transistor than in a Si transistor. Accordingly, when an OS transistor is used as the driving transistor included in the pixel circuit, the amount of current flowing between the source and the drain can be finely set by a change in gate-source voltage; thus, the amount of current flowing through the light-emitting device can be controlled. Therefore, the number of gray levels in the pixel circuit can be increased.

In addition, regarding saturation characteristics of current flowing when a transistor operates in a saturation region, even in the case where the source-drain voltage of an OS transistor gradually increases, more stable current (saturation current) can be fed through the OS transistor than through a Si transistor. Thus, by using an OS transistor as the driving transistor, stable current can be fed through the light-emitting device even when the current-voltage characteristics of EL devices vary, for example. In other words, when the OS transistor operates in the saturation region, the source-drain current hardly changes even with an increase in the source-drain voltage; thus, the emission luminance of the light-emitting device can be stable.

As described above, with use of an OS transistor as the driving transistor included in the pixel circuit, it is possible to achieve “reduction in power consumption”, “increase in emission luminance”, “increase in the number of gray levels”, “inhibition of variation in light-emitting devices”, and the like.

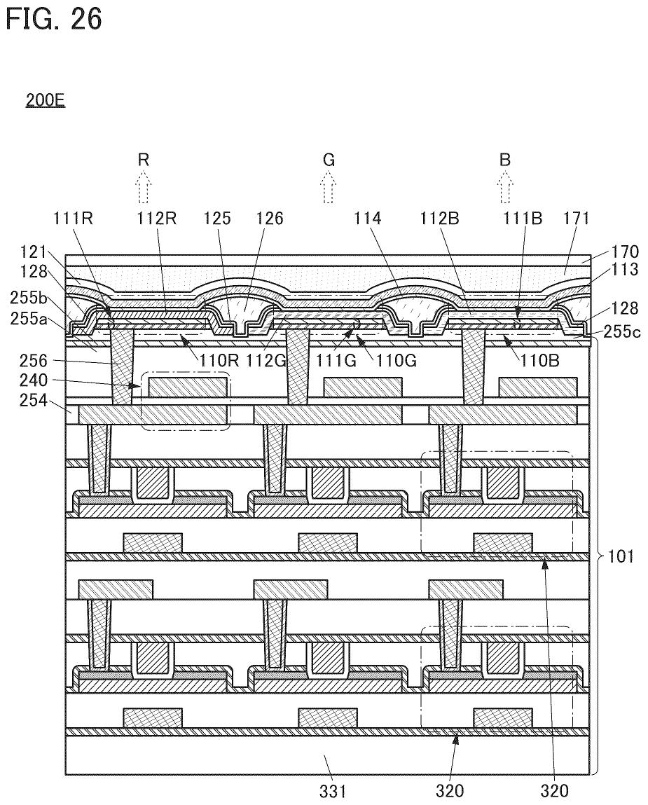

Note that a film of a metal oxide used for a semiconductor layer of an OS transistor can be formed to be thin, and thus OS transistors can be stacked. For example, as in the display panel 200E illustrated in FIG. 26, two OS transistors may be stacked. Alternatively, three or more OS transistors may be stacked.

### Display Panel 200F

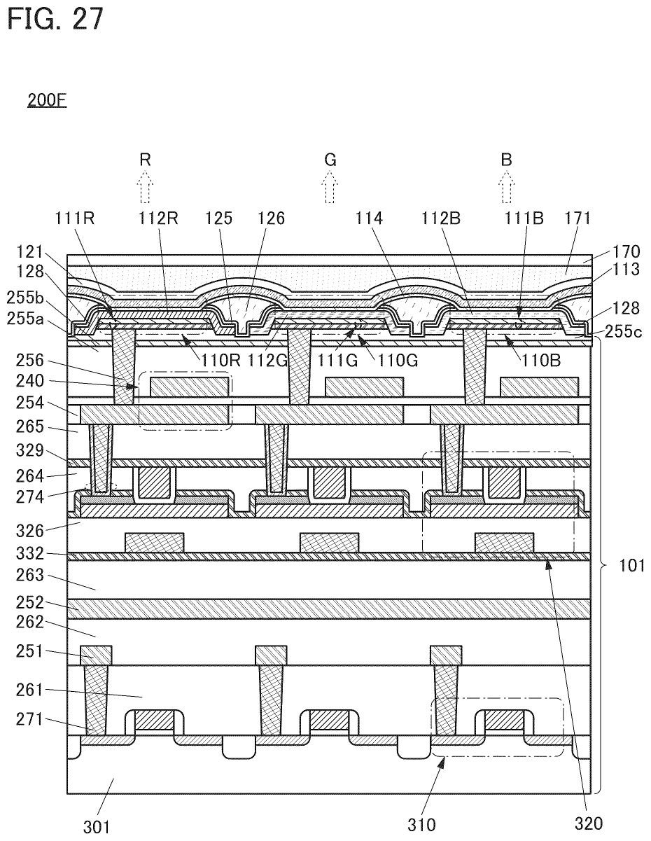

The display panel 200F illustrated in FIG. 27 has a structure in which the transistor 310 whose channel is formed in the substrate 301 and the transistor 320 including a metal oxide in the semiconductor layer where the channel is formed are stacked. A film of a metal oxide used for a semiconductor layer of an OS transistor can be formed to be thin, and thus the OS transistor can be formed to be stacked over a Si transistor.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistor 320 is provided over the insulating layer 332. Moreover, the insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. In addition, the transistor 310 can be used as a transistor included in the pixel circuit or a transistor included in a driver circuit (a gate line driver circuit or a source line driver circuit) for driving the pixel circuit. Furthermore, the transistor 310 and the transistor 320 can be used as transistors included in a variety of circuits such as an arithmetic circuit or a memory circuit.

With such a structure, not only the pixel circuit but also the driver circuit and the like can be formed directly under the light-emitting devices; thus, the display panel can be reduced in size as compared with the case where the driver circuit is provided around a display region.

### Display Panel 200G

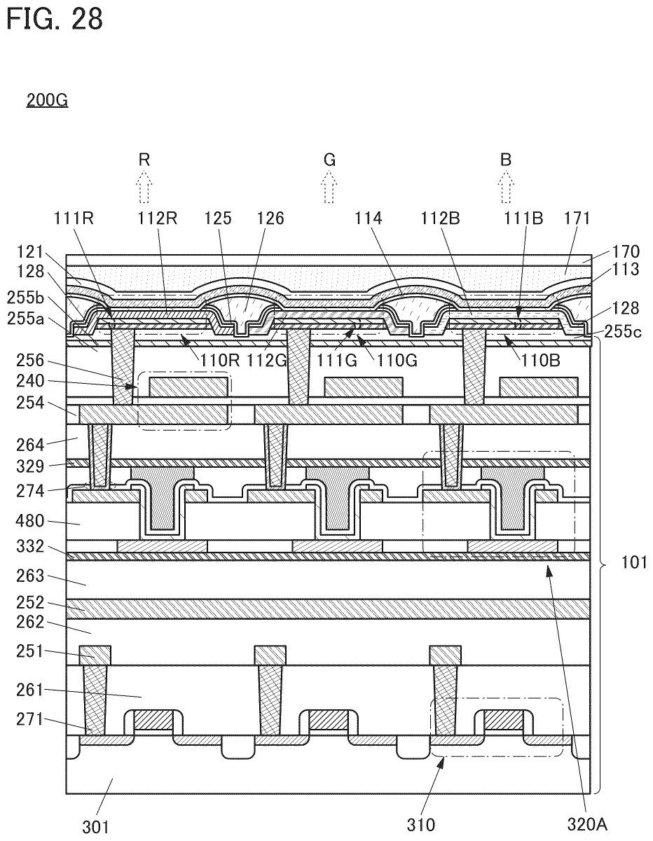

A display panel 200G illustrated in FIG. 28 has a structure in which the transistor 320 in the display panel 200F illustrated in FIG. 27 is replaced with a transistor 320A (vertical transistor). Note that the structure in which the transistor 320 is replaced with the transistor 320A can also be employed for the display panel 200D illustrated in FIG. 25.

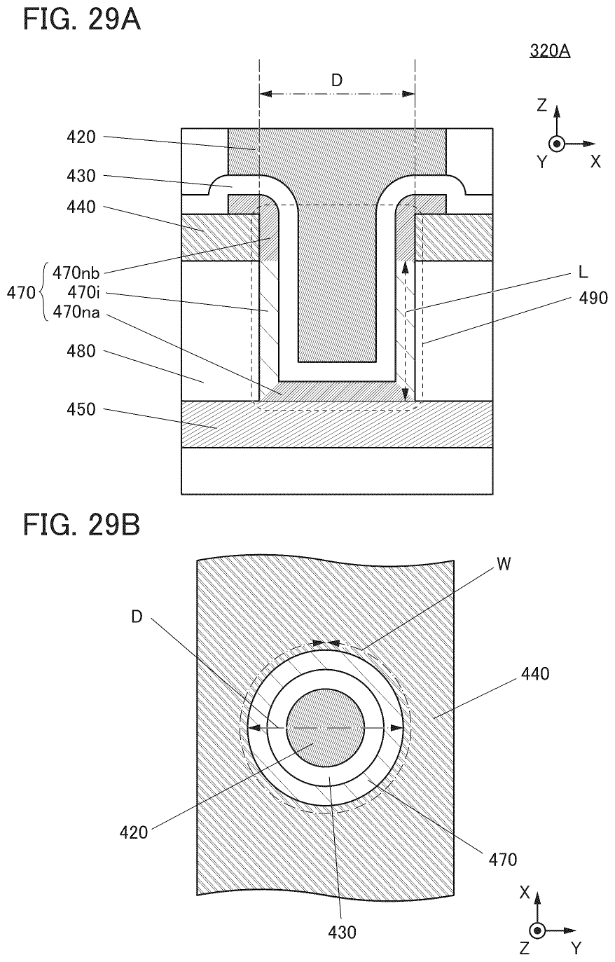

FIG. 29A is a cross-sectional view taken along the XZ plane of the transistor 320A. FIG. 29B is a cross-sectional view taken along the XY plane including a wiring 440.

The transistor 320A includes a semiconductor layer 470, an insulating layer 430, and a conductive layer 420. In the transistor 320A, the semiconductor layer 470 functions as a semiconductor layer, the insulating layer 430 functions as a gate insulating layer, and the conductive layer 420 functions as a gate electrode. A wiring 450 includes a region functioning as one of a source electrode and a drain electrode. The wiring 440 includes a region functioning as the other of the source electrode and the drain electrode.

An opening portion 490 reaching the wiring 450 is provided to penetrate the wiring 440 and an insulating layer 480. The opening portion 490 has a pillar shape with a substantially circular top surface. With this structure, the transistor can be miniaturized or highly integrated. Note that the side surface of the opening portion 490 is preferably perpendicular to the top surface of the wiring 450.

At least part of the semiconductor layer 470 is placed in the opening portion 490. Note that the semiconductor layer 470 includes a region in contact with the top surface of the wiring 450, a region in contact with the side surface of the wiring 440, and a region in contact with the side surface of the insulating layer 480 in the opening portion 490.

The insulating layer 430 is placed so that at least part thereof covers the opening portion 490. The conductive layer 420 is placed so that at least part thereof is positioned in the opening portion 490. The conductive layer 420 is preferably provided so as to be embedded in the opening portion 490, and preferably has a substantially circular top surface shape for a higher degree of integration.

As illustrated in FIG. 29A, the semiconductor layer 470 includes a region 470i, and a region 470na and a region 470nb provided so that the region 470i is interposed therebetween.

The region 470na is a region of the semiconductor layer 470 that is in contact with the wiring 450. At least part of the region 470na functions as one of a source region and a drain region of the transistor 320A. The region 470nb is a region of the semiconductor layer 470 that is in contact with the wiring 440. At least part of the region 470nb functions as the other of the source region and the drain region of the transistor 320A. As illustrated in FIG. 29B, the wiring 440 is in contact with all the outer periphery of the semiconductor layer 470. Thus, the other of the source region and the drain region of the transistor 320A can be formed in all the outer periphery of a portion of the semiconductor layer 470 that is formed in the same layer as the wiring 440.

The region 470i is a region interposed between the region 470na and the region 470nb in the semiconductor layer 470. At least part of the region 470i functions as a channel formation region of the transistor 320A. That is, the channel formation region of the transistor 320A is formed in part of the semiconductor layer 470 that is positioned in a region between the wiring 450 and the wiring 440. It can be said that the channel formation region of the transistor 320A is positioned in a region of the semiconductor layer 470 that is in contact with the insulating layer 480 or a region in the vicinity thereof.

The channel length of the transistor 320A is a distance between the source region and the drain region. In other words, the channel length of the transistor 320A is determined by the thickness of the insulating layer 480 over the wiring 450. In FIG. 29A, a channel length L of the transistor 320A is indicated by a dashed double-headed arrow. In the cross-sectional view, the channel length L is the distance between an end portion of the region where the semiconductor layer 470 is in contact with the wiring 450 and an end portion of the region where the semiconductor layer 470 is in contact with the wiring 440. That is, the channel length L corresponds to the length of the side surface of the insulating layer 480 on the opening portion 490 side in the cross-sectional view.

In a planar transistor, the channel length is determined by the light exposure limit of photolithography; however, in one embodiment of the present invention, the channel length can be determined by the thickness of the insulating layer 480. Thus, the transistor 320A can have an extremely short channel length less than or equal to the light exposure limit of photolithography (e.g., less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm, and greater than or equal to 5 nm, greater than or equal to 7 nm, or greater than or equal to 10 nm). In that case, the transistor 320A can have a higher on-state current.

In addition, as described above, the channel formation region, the source region, and the drain region can be formed in the opening portion 490. Thus, the occupation area of the transistor 320A can be reduced as compared with a planar transistor in which a channel formation region, a source region, and a drain region are provided separately on the XY plane. Accordingly, the pixel density can be increased.

The transistor including the channel formation region along the side surface of the insulating layer 480 in the opening portion 490 in the above-described manner is also referred to as a vertical transistor.

Furthermore, also in the XY plane including the channel formation region in the semiconductor layer 470, as in FIG. 29B, the semiconductor layer 470, the insulating layer 430, and the conductive layer 420 are provided concentrically. Thus, the side surface of the conductive layer 420 provided at the center faces the side surface of the semiconductor layer 470 with the insulating layer 430 therebetween. That is, in the top view, all the circumference of the semiconductor layer 470 serves as the channel formation region. In this case, for example, the channel width of the transistor 320A is determined by the length of the outer periphery of the semiconductor layer 470. In other words, the channel width of the transistor 320A is determined by the maximum width of the opening portion 490 (the maximum diameter in the case where the opening portion 490 is circular in the top view). In FIG. 29A and FIG. 29B, a maximum width D of the opening portion 490 is indicated by a dashed double-dotted double-headed arrow. In FIG. 29B, a channel width W of the transistor 320A is indicated by a dashed-dotted double-headed arrow. By increasing the maximum width D of the opening portion 490, the channel width per unit area can be increased and the on-state current can be increased.

In the case where the opening portion 490 is formed by a photolithography method, the maximum width D of the opening portion 490 is determined by the light exposure limit of photolithography. In addition, the maximum width D of the opening portion 490 is determined by the thicknesses of the semiconductor layer 470, the insulating layer 430, and the conductive layer 420 provided in the opening portion 490. The maximum width D of the opening portion 490 is preferably, for example, greater than or equal to 200 nm, greater than or equal to 300 nm, greater than or equal to 400 nm, or greater than or equal to 500 nm, and less than 5 μm, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm. In the case where the opening portion 490 is circular in the top view, the maximum width D of the opening portion 490 corresponds to the diameter of the opening portion 490, and the channel width W can be calculated to be “D×π”.

In the memory device of one embodiment of the present invention, the channel length L of the transistor 320A is preferably shorter than at least the channel width W of the transistor 320A. The channel length L of the transistor 320A of one embodiment of the present invention is greater than or equal to 0.1 times and less than or equal to 0.99 times, preferably greater than or equal to 0.5 times and less than or equal to 0.8 times the channel width W of the transistor 320A. This structure enables a transistor with favorable electrical characteristics and high reliability.

In the case where the opening portion 490 is formed to be substantially circular in the top view, the semiconductor layer 470, the insulating layer 430, and the conductive layer 420 are provided concentrically. This makes the distance between the conductive layer 420 and the semiconductor layer 470 substantially uniform, so that a gate electric field can be substantially uniformly applied to the semiconductor layer 470.

It is preferable that the channel formation region of the transistor including an oxide semiconductor in a semiconductor layer contain fewer oxygen vacancies or have a lower concentration of an impurity such as hydrogen, nitrogen, or a metal element than the source region and the drain region. In some cases, a defect that is an oxygen vacancy into which hydrogen enters (hereinafter sometimes referred to as V_{O}H) generates an electron serving as a carrier, so that it is preferable that V_{O}H be also decreased in the channel formation region. Thus, the channel formation region of the transistor is a high-resistance region having a low carrier concentration. Accordingly, the channel formation region of the transistor can be regarded as being i-type (intrinsic) or substantially i-type.

The source region and the drain region of the transistor including an oxide semiconductor in a semiconductor layer include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

Although the opening portion 490 is provided so that the side surface of the opening portion 490 is perpendicular to the top surface of the wiring 450 in FIG. 29A and the like, the present invention is not limited thereto. The side surface of the opening portion 490 may have a tapered shape, for example.

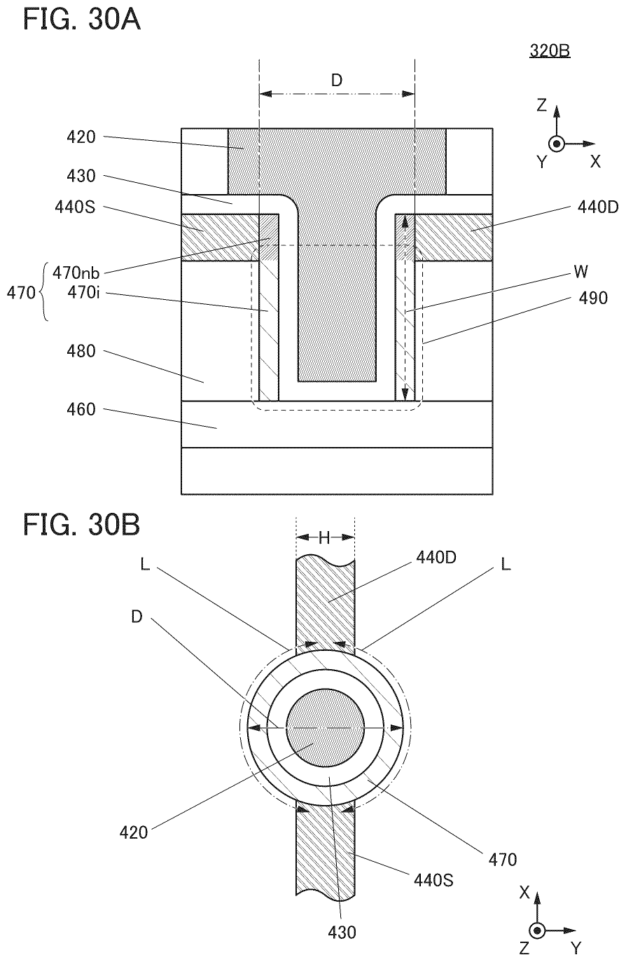

FIG. 30A is a cross-sectional view taken along the XZ plane of a transistor 320B having a structure different from that in FIG. 29. FIG. 30B is a cross-sectional view taken along the XY plane.

The transistor 320B is different from the transistor 320A mainly in not including the wiring 450, in being provided over an insulating layer 460, in including a wiring 440S and a wiring 440D instead of the wiring 440, and in including the semiconductor layer 470 with a shape different from that in the transistor 320A. The wiring 440S has a function of a source electrode, and the wiring 440D has a function of a drain electrode.

The semiconductor layer 470 has a ring-like shape. Specifically, the semiconductor layer 470 includes a region in contact with the side surface of the wiring 440S, a region in contact with the side surface of the wiring 440D, and a region in contact with the side surface of the insulating layer 480 in the opening portion 490. Here, the semiconductor layer 470 is not in contact with the top surfaces of the wiring 440S and the wiring 440D. The semiconductor layer 470 having such a shape can be formed by processing employing anisotropic etching, for example.

As illustrated in FIG. 30B, a width H of each of the wiring 440S and the wiring 440D is smaller than the maximum width D of the opening portion 490. In this case, the circumferential direction of the opening portion 490 corresponds to the channel length direction of the transistor 320B. Here, the semiconductor layer 470 has a ring-like shape, so that there are two types of current paths (i.e., channels) from the wiring 440S to the wiring 440D. Note that the semiconductor layer 470 does not necessarily have a ring-like shape and may be in contact with both the wiring 440S and the wiring 440D.

The channel length can be controlled by the shape and size of the opening portion 490. For example, in the case where the channel length is desired to be increased, the perimeter of the opening portion 490 is made long. Although the example in which the opening portion 490 has a circular shape in the plan view is described, the present invention is not limited thereto. For example, the opening portion 490 can have an elliptical shape or a quadrangular shape with rounded corners besides the circular shape in the plan view. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased. Alternatively, an elliptical shape, a polygonal shape with rounded corners, a closed curve in which a straight line and a curve are combined, or the like can be employed. In that case, the maximum width of the opening portion 490 is calculated as appropriate in accordance with the shape of the uppermost portion of the opening portion 490. For example, in the case where the opening portion 490 is square or rectangular in the plan view, the maximum width of the opening portion 490 is preferably the length of a diagonal line of the uppermost portion of the opening portion 490.

As illustrated in FIG. 30A, the height of the semiconductor layer 470 is the channel width W of the transistor 320B. Thus, the channel width W of the transistor 320B can be controlled by the thickness of the insulating layer 480. Thus, the transistor 320B can have an extremely small channel width less than or equal to the light exposure limit of photolithography (e.g., less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm, and greater than or equal to 5 nm, greater than or equal to 7 nm, or greater than or equal to 10 nm).

The transistor 320A is a transistor that has an extremely short channel length and can have a large channel width, and can achieve a high on-state current. Meanwhile, the transistor 320B is a transistor that has an extremely small channel width and can have a long channel length, and can achieve an appropriate on-state current and can be easily designed. The transistor 320A and the transistor 320B can share some of the manufacturing steps and can be separately formed over the same substrate. For example, in a display device, the transistor 320B can be used as a driving transistor for controlling current flowing through a light-emitting element, and the transistor 320A can be used as a transistor functioning as a switch.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

At least part of the structure examples, the drawings corresponding thereto, and the like described as an example in this embodiment can be combined with the other structure examples, the other drawings corresponding thereto, and the like as appropriate.

### Embodiment 4

In this embodiment, electronic devices of embodiments of the present invention will be described.

Electronic devices in this embodiment each include the display device of one embodiment of the present invention in a display portion. The display device of one embodiment of the present invention can easily achieve higher definition and higher resolution. Thus, the display device of one embodiment of the present invention can be used for display portions of a variety of electronic devices.

In particular, the display device of one embodiment of the present invention can have higher definition, and thus can be suitably used for an electronic device having a comparatively small display portion. Examples of such an electronic device include wristwatch-type and bracelet-type information terminal devices (wearable devices); a wearable device that can be worn on a head, such as a VR device like an HMD, a glasses-type AR device, or an MR device; and the like.

The resolution of the display device of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, the resolution of 4K, 8K, or higher is preferable. In addition, the pixel density (definition) of the display device of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With use of such a display device with one or both of high resolution and high definition, higher realistic sensation, sense of depth, and the like can be obtained. Furthermore, there is no particular limitation on the screen ratio (aspect ratio) of the display device of one embodiment of the present invention. For example, the display device is compatible with a variety of screen ratios such as 1:1 (a square), 4:3, 16:9, and 16:10. In particular, compared to a square screen shape, a landscape screen with an aspect ratio of 16:9 or the like is preferable for AR use.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data recorded in a recording medium.

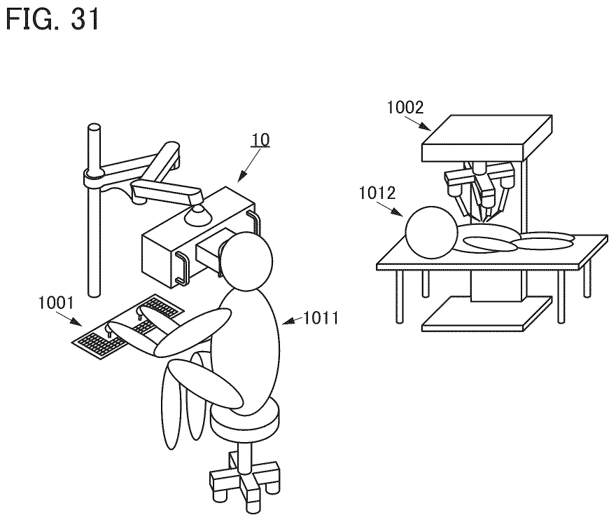

An example in which the electronic device 10 is utilized in a medical site will be described with reference to FIG. 31. FIG. 31 illustrates a state where medical treatment is performed using a medical treatment support robot 1002.

A doctor 1011 operates the medical treatment support robot 1002 with use of an operation portion 1001 to give appropriate medical treatment to a patient 1012. The electronic device 10 and the operation portion 1001 that are used by the doctor 1011 may be placed in a medical treatment room that is the same as or different from a medical treatment room where the medical treatment support robot 1002 is placed. In particular, placement of the electronic device 10 and the operation portion 1001 in a different medical treatment room from the medical treatment support robot 1002 enables remote medical treatment.

The medical treatment support robot 1002 is provided with a plurality of arms, a camera, and the like. The tip of each of the plurality of arms is provided with a forceps, a scalpel, or the like.

The doctor 1011 uses the electronic device 10. A display portion of the electronic device 10 performs real-time display of video taken by the camera of the medical treatment support robot 1002. The doctor 1011 can perform medical treatment while looking at the video.

In addition, the video taken by the camera of the medical treatment support robot 1002 can be displayed also on a monitor device that is separately provided. Accordingly, other doctors and the like can see the situation of the medical treatment performed by the doctor 1011 in real time without interrupting the doctor 1011. Here, the monitor device may be placed in a medical treatment room or placed in another room. For example, when a resident physician or the like sees the situation of the medical treatment performed by the doctor 1011 through a monitor device placed in the medical treatment room, the resident physician or the like can feel the real atmosphere of a treatment environment.

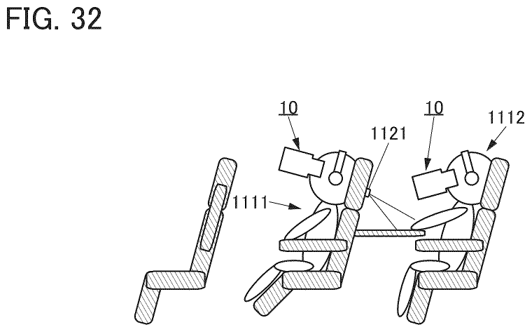

The electronic device 10 may be provided inside a moving object such as an airplane, a bus, a ship, a train, or an automobile. An example in which the electronic device 10 is used in an airplane will be described with reference to FIG. 32. FIG. 32 illustrates a state where airplane passengers each use the electronic device 10. Note that FIG. 32 illustrates, as the electronic device 10, only a housing in which a display device is incorporated.

A passenger 1111 sees an image with use of the electronic device 10. In addition, the passenger 1111 wears headphones and listens to audio data output with or without a wire.

The passenger 1111 sees the image while a viewing angle is widened, and thus can obtain a sense of immersion and a realistic sensation. The image displayed by the electronic device 10 is not seen by an adjacent or rear passenger or a flight attendant, so that the passenger 1111 can see the image comfortably without caring about surrounding people.

A passenger 1112 also sees an image with use of the electronic device 10. The passenger 1112 sees the image while a viewing angle is widened, and thus can obtain a sense of immersion and a realistic sensation.

The electronic device 10 is preferably capable of executing a variety of applications such as reading and editing texts, music reproduction, and a computer game. The electronic device 10 preferably has a communication function. For example, the passenger 1112 can read and edit texts and send and receive e-mails with use of an information input device 1121 such as a virtual keyboard or gesture recognition. Thus, the passenger 1112 can exchange information with others comfortably without caring about surrounding people.

With use of the electronic devices 10, a plurality of people can see the same image and share experience. For example, the electronic devices 10 can be suitably used in amusement facilities, such as an amusement park and a game arcade, or an exhibition hall. The electronic devices 10 can also be applied to exhibition in a planetarium, an art museum, a science museum, a museum, an aquarium, and the like. Moreover, for example, the electronic devices 10 can also be suitably used in facilities that provide simulated experience of winter sports such as skiing, marine sports such as diving, and a variety of other sports. Furthermore, for example, the electronic devices 10 can also be suitably used in facilities that provide simulated experience of travel to a tourism destination, space, or the like.

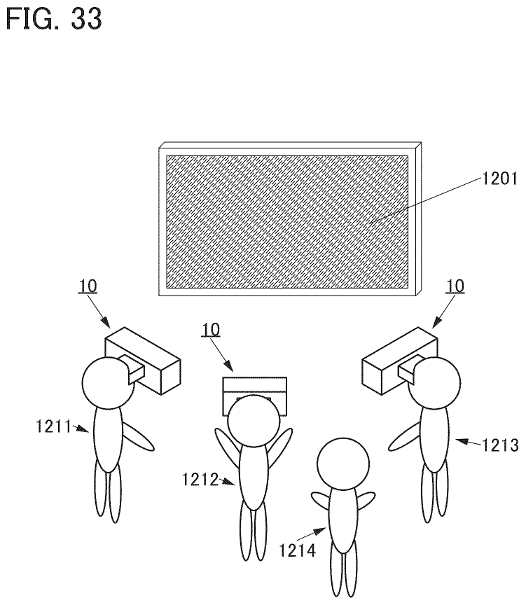

An example of a case where a plurality of people use the electronic devices 10 in an exhibition hall or the like will be described with reference to FIG. 33. FIG. 33 illustrates a state where the plurality of people share an image. Note that FIG. 33 illustrates, as the electronic device 10, only the housing in which the display device is incorporated.

A user 1211, a user 1212, and a user 1213 share an image with use of the electronic devices 10. The user 1211 to the user 1213 each see the image while a viewing angle is widened, and thus can obtain a sense of immersion and a realistic sensation.

The image seen by the user 1211 to the user 1213 may also be displayed on a monitor device 1201. In this case, the users can share the image also with a person who does not use the electronic device 10.

Since the electronic device 10 is easily attached and detached, the electronic device 10 can be rapidly transferred to another person (e.g., a member 1214).

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

At least part of the structure examples, the drawings corresponding thereto, and the like described as an example in this embodiment can be combined with the other structure examples, the other drawings corresponding thereto, and the like as appropriate.

### Embodiment 5

In this embodiment, a display panel that can be applied to the display device of one embodiment of the present invention will be described.

The display panel includes a display portion, and the pixel density (definition) of the display portion is preferably higher than or equal to 1000 ppi and lower than or equal to 10000 ppi. For example, the pixel density can be higher than or equal to 2000 ppi and lower than or equal to 6000 ppi or higher than or equal to 3000 ppi and lower than or equal to 5000 ppi.

Note that the display panel may be configured so that the load during video signal generation (rendering) is reduced. Processing for reducing the load during video signal generation is also referred to as “foveated rendering”. The use of the display panel capable of the foveated rendering processing can reduce power consumption.

Note that there is no particular limitation on the screen ratio (aspect ratio) of the display portion. For example, the display portion is compatible with a variety of screen ratios such as 1:1 (a square), 4:3, 16:9, and 16:10. There is no particular limitation on the external shape of the display portion, and a variety of shapes such as a square, a rectangle, and a circle can be employed.

Note that the display panel may have flexibility. When the display panel has flexibility, a display portion with a curved display surface can be provided. In that case, for example, the display surface preferably has a curved shape like an eyeball, a cornea, a crystalline lens, or the like. When the display surface of the display portion is curved, the display portion can emit an image along the curved display surface. Accordingly, the viewing angle can be widened even without correcting an image emitted from the display surface. Furthermore, when combined with a wide-angle lens (a lens with a wide angle of view or a lens with a short focal length), the display panel can achieve a wider viewing angle.

To make the display panel have flexibility, a substrate of the display panel preferably has flexibility. Note that in the case where a transistor whose channel formation region is formed in a semiconductor substrate (e.g., a single crystal silicon substrate) is used as a transistor provided below a light-emitting element, the display panel is difficult to have flexibility. Thus, the transistor provided below the light-emitting element is preferably formed using a semiconductor layer that can be formed as a thin film. For the semiconductor layer, for example, the metal oxide that is described in Embodiment 3 and can be used for the semiconductor layer is preferably used. With such a structure, the display panel having flexibility can be obtained. Note that the semiconductor layer may be formed using a material other than the above metal oxide as long as the semiconductor layer is formed using a material with which a thin film can be formed. For example, amorphous silicon, microcrystalline silicon, polycrystalline silicon, or the like may be used.

Here, a relation between the size of a display portion of a display device (also referred to as a “size of a display region”) and a light-exposure region of a light-exposure apparatus will be described. Note that in the following description, the display portion of the display device and the light-exposure region of the light-exposure apparatus are described as a display portion 900 and a light-exposure region 910, respectively.

### Size of Display Region and Light-Exposure Region

By considering the size of the display region of the display device based on the light-exposure region 910 of the light-exposure apparatus, the display device can be manufactured at optimal manufacturing costs. For example, as the light-exposure apparatus, a stepper, a scanner, and the like can be used. A light source that can be used for the light-exposure apparatus has a wavelength of 13 nm (EUV (Extreme Ultra Violet)), 157 nm (F₂), 193 nm (ArF), 248 nm (KrF), 308 nm (XeCl), 365 nm (an i-line), 436 nm (a g-line), and the like. With the light source having a short wavelength, a high definition display device or a miniaturized display device can be obtained.

Note that as the maximum value of the light-exposure region 910 of the light-exposure apparatus, [26 mm×33 mm] is a current mainstream; therefore, the description below is considered with reference to [26 mm×33 mm]. When the maximum value of the light-exposure region 910 is [26 mm×33 mm], the size of the display region that can be obtained with one light exposure (1 shot) is [26 mm×33 mm].

As described above, there is no limitation on the screen ratio (aspect ratio) of the display portion 900. The aspect ratio of the display portion 900 can be 1:1, 4:3, 16:9, 16:10, or the like.

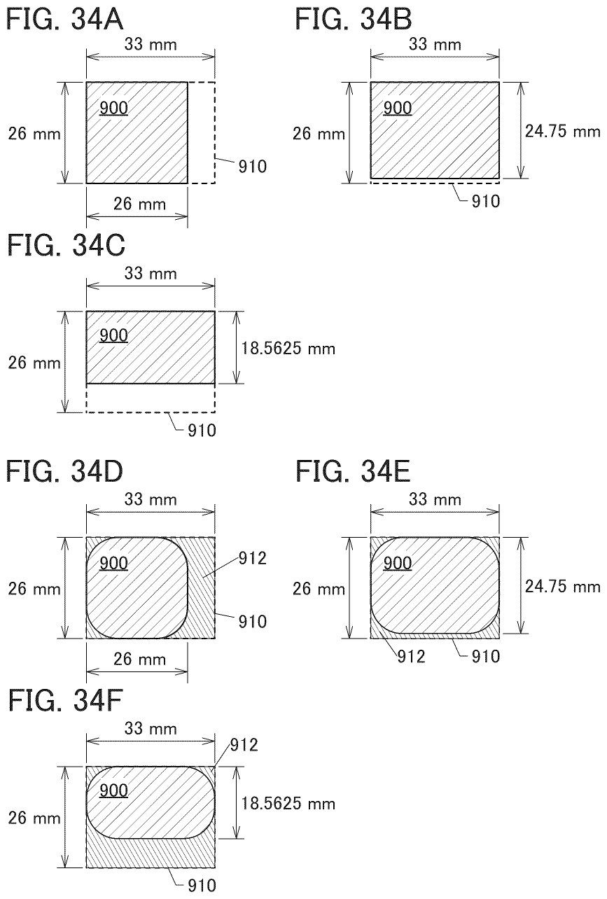

As illustrated in FIG. 34A to FIG. 34C, in the case where the maximum value of the light-exposure region 910 of the light-exposure apparatus is [26 mm×33 mm], the maximum size of a display region of a display device that can be manufactured in one light exposure is [26 mm×26 mm] when the aspect ratio is 1:1, [33 mm×24.75 mm] when the aspect ratio is 4:3, and [33 mm×18.5625 mm] when the aspect ratio is 16:9.

Note that the above values are each the maximum size of the display region of the display device; thus, the actual external dimension of the display device is larger than or equal to the size of the display region of the display device. In addition, the aspect ratio of the external dimension of the display device may be the same as or different from the aspect ratio of the display region of the display device.

FIG. 34D to FIG. 34F show modification examples of FIG. 34A to FIG. 34C.

In each of FIG. 34D to FIG. 34F, a corner portion of the display portion 900 has a filleted shape (a shape obtained by rounding processing on the corner portion). Although not illustrated, the corner portion of the display portion 900 may have a chamfered shape. When the corner portion of the display portion 900 has a filleted or chamfered shape, the well-designed display portion can be provided. A lens used for a display unit has a circular shape in many cases; thus, the corner portion of the display portion 900 is difficult to use efficiently. Thus, even when the corner portion of the display portion 900 has a rounded shape or a chamfered shape, the display quality of an image seen by a user is less likely to be impaired.

Note that in each of FIG. 34D to FIG. 34F, a region 912 represents a region where the display portion 900 and the light-exposure region 910 do not overlap with each other. The region 912 is provided with an alignment marker or the like used in light exposure. When the region 912 is provided with the alignment marker or the like, chips can be efficiently taken from a Si wafer. That is, a display panel can be provided at lower manufacturing costs. Note that in the region 912, a marker or the like necessary for the manufacturing process, such as a length measurement marker or an evaporation marker, may be placed in addition to the alignment marker.

### REFERENCE NUMERALS

10: electronic device, 11: housing, 12: point, 13a: arm, 13b: arm, 13c: arm, 13: articulated arm, 16: support rod, 18L: handle, 18R: handle, 19: cushion, 20A: display device, 20B: display device, 20C: display device, 20: display device, 21L: display unit, 21R: display unit, 31C: display panel, 31L: display panel, 31R: display panel, 31: display panel, 32L: display portion, 32R: display portion, 32: display portion, 33L: display panel, 33R: display panel, 33: display panel, 34L: display portion, 34R: display portion, 34: display portion, 35L: external light, 35R: external light, 41L: mirror, 41R: mirror, 41: mirror, 42L: lens, 42L_1: lens, 42L_2: lens, 42R: lens, 42R_1: lens, 42R_2: lens, 42: lens, 43L: mirror, 43R: mirror, 43: mirror, 44L: lens, 44R: lens, 44: lens, 45L: half mirror, 45R: half mirror, 45: half mirror, 46L: half mirror, 46R: half mirror, 46: half mirror, 48L: mirror, 48R: mirror, 48: mirror, 49L: mirror, 49R: mirror, 49: mirror, 60L: left eye, 60R: right eye, 70: image, 71: image, 72: image, 100a: display panel, 100b: display panel, 100: display panel, 101: substrate, 110a: light-emitting element, 110B: light-emitting element, 110b: light-emitting element, 110c: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 116B: coloring layer, 116G: coloring layer, 116R: coloring layer, 121: protective layer, 122: insulating layer, 123: insulating layer, 124a: pixel, 124b: pixel, 125: insulating layer, 126: resin layer, 128: layer, 140: connection portion, 150: pixel, 170: substrate, 171: adhesive layer, 200A: display panel, 200B: display panel, 200C: display panel, 200D: display panel, 200E: display panel, 200F: display panel, 200G: display panel, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 420: conductive layer, 430: insulating layer, 440D: wiring, 440S: wiring, 440: wiring, 450: wiring, 460: insulating layer, 470i: region, 470na: region, 470nb: region, 470: semiconductor layer, 480: insulating layer, 490: opening portion, 1001: operation portion, 1002: medical treatment support robot, 1011: doctor, 1012: patient, 1111: passenger, 1112: passenger, 1121: information input device, 1201: monitor device, 1211: user, 1212: user, 1213: user, 1214: member

1. A display device comprising:
a first display unit and a second display unit,
wherein the first display unit and the second display unit each comprise a display portion, a first mirror, a second mirror, a first lens, and a second lens,
wherein an image emitted from the display portion enters the second lens through the first mirror and the second mirror,
wherein the first mirror is positioned on a normal line passing through a center of gravity of the display portion,
wherein the second mirror is positioned on a straight line connecting centers of two lens surfaces of the second lens,
wherein the first mirror and the second mirror are placed so that their reflective surfaces are parallel to each other,
wherein the normal line passing through the center of gravity of the display portion and the straight line connecting the centers of the two lens surfaces of the second lens are not aligned with each other, and
wherein the first lens is positioned on an optical path through which the image emitted from the display portion enters the second lens.

2. The display device according to claim 1, wherein the first lens is positioned between the first mirror and the second mirror.

3. The display device according to claim 1, wherein the first lens is positioned between the second mirror and the second lens.

4. The display device according to claim 2,
wherein the first lens is configured to be a relay lens, and
wherein the second lens as-is configured to be an eyepiece lens.

5. The display device according to claim 2,
wherein the first display unit comprises a first display panel,
wherein the first display panel comprises the display portion of the first display unit,
wherein the second display unit comprises a second display panel, and
wherein the second display panel comprises the display portion of the second display unit.

6. The display device according to claim 2,
wherein the first display unit and the second display unit comprise a third display panel, and
wherein the third display panel comprises the display portion of the first display unit and the display portion of the second display unit.

7. A display device comprising:
a first display unit and a second display unit,
wherein the first display unit and the second display unit each comprise a display portion, a first mirror, a second mirror, a third mirror, a fourth mirror, a first lens, a second lens, and a third lens,
wherein the third mirror is positioned on a normal line passing through a center of gravity of the display portion,
wherein the first mirror is provided between the third mirror and the display portion,
wherein the second mirror is positioned on a straight line connecting centers of two lens surfaces of the third lens,
wherein the fourth mirror is provided between the second mirror and the third lens,
wherein the first lens is positioned between the first mirror and the second mirror,
wherein the second lens is positioned between the third mirror and the fourth mirror,
wherein in a case where the fourth mirror is not positioned on the straight line connecting the centers of the two lens surfaces of the third lens, an image emitted from the display portion enters the third lens through the first mirror, the first lens, and the second mirror, and
wherein in a case where the fourth mirror is positioned on the straight line connecting the centers of the two lens surfaces of the third lens, an image emitted from the display portion enters the third lens through the third mirror, the second lens, and the fourth mirror.

8. The display device according to claim 7,
wherein the fourth mirror comprises a mechanism capable of one or both of translational movement and rotational movement.

9. The display device according to claim 7,
wherein the first lens and the second lens are configured to be relay lenses, and
wherein the third lens is configured to be an eyepiece lens.

10. The display device according to claim 7,
wherein the first display unit comprises a first display panel,
wherein the first display panel comprises the display portion of the first display unit,
wherein the second display unit comprises a second display panel, and
wherein the second display panel comprises the display portion of the second display unit.

11. The display device according to claim 7,
wherein the first display unit and the second display unit comprise a third display panel, and
wherein the third display panel comprises the display portion of the first display unit and the display portion of the second display unit.

12. An electronic device comprising:
a housing in which the display device according to claim 1 is incorporated and an arm fastened to an upper portion of the housing,
wherein the arm is connected so as to be revolvable centering around a first point.
